(19) United States
(12) Patent Application Publication
(10) Pub. No.: US 2026/0013044 A1
(43) Pub. Date: Jan. 8, 2026

(54) ELECTRONIC DEVICE AND MANUFACTURING METHOD THEREOF

(71) Applicant: InnoLux Corporation, Miao-Li County (TW)

(72) Inventors: Po-Yun HSU, Miao-Li County (TW); Ker-Yih KAO, Miao-Li County (TW)

(73) Assignee: InnoLux Corporation, Miao-Li County (TW)

(21) Appl. No.: 19/227,513

(22) Filed: Jun. 4, 2025

Related U.S. Application Data
(60) Provisional application No. 63/667,136, filed on Jul. 3, 2024.

(30) Foreign Application Priority Data
Dec. 20, 2024 (CN) 202411884268.6

(51) Int. Cl. H05K 1/11; H05K 1/18; H05K 3/40

(52) U.S. Cl. CPC H05K 1/115; H05K 1/183; H05K 3/4038; H05K 2201/096; H05K 2201/09827

(57) ABSTRACT

An electronic device and a manufacturing method thereof are provided. The electronic device includes a substrate and a first buffer layer. The substrate has a via. The substrate includes a first base layer and a second base layer. The first base layer includes a first sub via penetrating the first base layer. The second base layer is bonded to the first base layer. The second base layer includes a second sub via penetrating the second base layer. The first sub via and the second sub via overlap each other to define the via. The first buffer layer is disposed in the via. The first sub via has a pore size, the first sub via and the second sub via have an overlapping region, the overlapping region has an overlapping width, and a difference between the pore size and the overlapping width ranges from 0.01 micrometers to 5 micrometers.

### CROSS REFERENCE TO RELATED APPLICATION

This application claims the benefit of U.S. Provisional Application No. 63/667,136, filed on Jul. 3, 2024. The content of the application is incorporated herein by reference.

### BACKGROUND OF THE DISCLOSURE

### 1. Field of the Disclosure

The present disclosure relates to an electronic device and a manufacturing method thereof, and more particularly to an electronic device including a substrate having via and a manufacturing method thereof.

### 2. Description of the Prior Art

In current electronic devices, vias may be provided in the substrate, and the conductive material may be disposed in the vias as wires to transmit electrical signals. However, when the aspect ratio of the via is too large, the conductive material may not be easily disposed in the deep of the via, which may lead to wire breakage, but not limited thereto. Therefore, to improve the manufacturing process of electronic device having vias with high aspect ratio is still an important issue in the present field.

### SUMMARY OF THE DISCLOSURE

The present disclosure aims at providing an electronic device and a manufacturing method thereof.

An electronic device is provided in the present disclosure. The electronic device includes a substrate and a first buffer layer. The substrate has a via. The substrate includes a first base layer and a second base layer. The first base layer includes a first sub via penetrating the first base layer. The second base layer is bonded to the first base layer. The second base layer includes a second sub via penetrating the second base layer. The first sub via and the second sub via overlap each other to define the via. The first buffer layer is disposed in at least a portion of the via. The first sub via has a pore size, the first sub via and the second sub via have an overlapping region, the overlapping region has an overlapping width, and a difference between the pore size and the overlapping width ranges from 0.01 micrometers to 5 micrometers.

A manufacturing method of an electronic device is provided by the present disclosure. The manufacturing method includes providing a first base layer, and forming a first sub via in the first base layer; providing a second base layer, and forming a second sub via in the second base layer; disposing a first conductive element in the first sub via; disposing a second conductive element in the second sub via; and bonding the first base layer and the second base layer to form a substrate, wherein the first sub via overlaps the second sub via to define a via. The first sub via has a pore size, the first sub via and the second sub via have an overlapping region, the overlapping region has an overlapping width, and a difference between the pore size and the overlapping width ranges from 0.01 micrometers to 5 micrometers.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to a first embodiment of the present disclosure.

FIG. 2 to FIG. 3 schematically illustrate a manufacturing process of the electronic device according to the first embodiment of the present disclosure.

FIG. 4 schematically illustrates a cross-sectional view of an electronic device according to a second embodiment of the present disclosure.

FIG. 5 schematically illustrates a cross-sectional view of an electronic device according to a third embodiment of the present disclosure.

FIG. 6 schematically illustrates a cross-sectional view of an electronic device according to a fourth embodiment of the present disclosure.

FIG. 7 schematically illustrates a cross-sectional view of an electronic device according to a fifth embodiment of the present disclosure.

FIG. 8 schematically illustrates a manufacturing process of an electronic device according to a sixth embodiment of the present disclosure.

FIG. 9 schematically illustrates a cross-sectional view of the electronic device according to the sixth embodiment of the present disclosure.

FIG. 10 schematically illustrates a manufacturing process of an electronic device according to a seventh embodiment of the present disclosure.

FIG. 11 schematically illustrates a cross-sectional view of the electronic device according to the seventh embodiment of the present disclosure.

FIG. 12 schematically illustrates a cross-sectional view of an electronic device according to an eighth embodiment of the present disclosure.

FIG. 13 schematically illustrates a cross-sectional view of an electronic device according to a ninth embodiment of the present disclosure.

FIG. 14 schematically illustrates a cross-sectional view of an electronic device according to a tenth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that in the present disclosure, when an element is referred to as being “disposed on” another element, the order of the process steps of the element and the another element are not limited. Or, in the present disclosure, when an element is referred to as being “disposed on” another element, it includes the case that the element is formed on a sidewall of the another element. When an element or layer is referred to as being “disposed on” or “connected to” another element or layer, it can be directly on or directly connected to the other element or layer, or intervening elements or layers may be presented (indirectly). In the present disclosure, when an element is referred to as being “disposed on” another element, the order of the process steps of the element and the another element are not limited. In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

In addition, any two values or directions used for comparison may have certain errors. In addition, the terms “equal to”, “equal”, “the same”, “approximately” or “substantially” are generally interpreted as being within ±20%, ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

According to the present disclosure, the depth, the thickness, the length, the width and the pore size may be measured through optical microscope (OM), electronic microscope (such as scanning electron microscope (SEM)) or other suitable ways, but not limited thereto.

In the present disclosure, the roughness may be judged by observing through SEM. On an uneven surface, it can be seen that the peaks and valleys of the surface have a distance of 0.15 micrometers (μm) to 1 μm. The measurement of the roughness may be performed by observing the undulations of the surface through SEM, transmission electron microscope (TEM), and the like at the same appropriate magnification, and taking a sample of a unit length (for example, 10 μm) to compare the undulation conditions as its roughness range. Here, “appropriate magnification” means that at least one surface can see the roughness (Rz) or average roughness (Ra) of at least 10 peaks under this magnification.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may be applied to a power module, a semiconductor package device, a display device, a light emitting device, a back-light device, an antenna device, a sensing device or a tiled device, but not limited thereto. The electronic device may be a foldable electronic device, a flexible electronic device or a stretchable electronic device. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The display device may be a non-self-emissive display device or a self-emissive display device. The sensing device may include a biosensor, a touch sensor, a fingerprint sensor, other suitable sensors or combinations of the above-mentioned sensors. The antenna device may for example include a liquid crystal antenna device or a non-liquid crystal antenna device. The tiled device may for example include a tiled display device or a tiled antenna device, but not limited thereto. The outline of the electronic device may be a rectangle, a circle, a polygon, a shape with curved edge or other suitable shapes. The electronic device may include electronic elements, wherein the electronic elements may include semiconductor elements. The semiconductor element may be the electronic element including a semiconductor layer or formed through a semiconductor process, but not limited thereto. The electronic elements for example include passive elements or active elements, such as capacitor, resistor, inductor, diode, transistor, integrated circuits, and the like. The diode may include a light emitting diode, a photo diode or a varactor diode. The light emitting diode may for example include an organic light emitting diode (OLED), a mini light emitting diode (mini LED), a micro light emitting diode (micro LED) or a quantum dot light emitting diode (QLED), but not limited thereto. It should be noted that the electronic device may be combinations of the above-mentioned devices, but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices. The manufacturing method of the electronic device of the present disclosure may for example be applied to a wafer-level package (WLP) process or a panel-level package (PLP) process, but not limited thereto. The manufacturing method of the electronic device of the present disclosure may include a chip-first process or a chip-last process, but not limited thereto. The electronic device may include system on a chip (SoC), system in a package (SiP), antenna in package (AiP), co-packaged optical (CPO) or combinations of the above-mentioned devices, but not limited thereto.

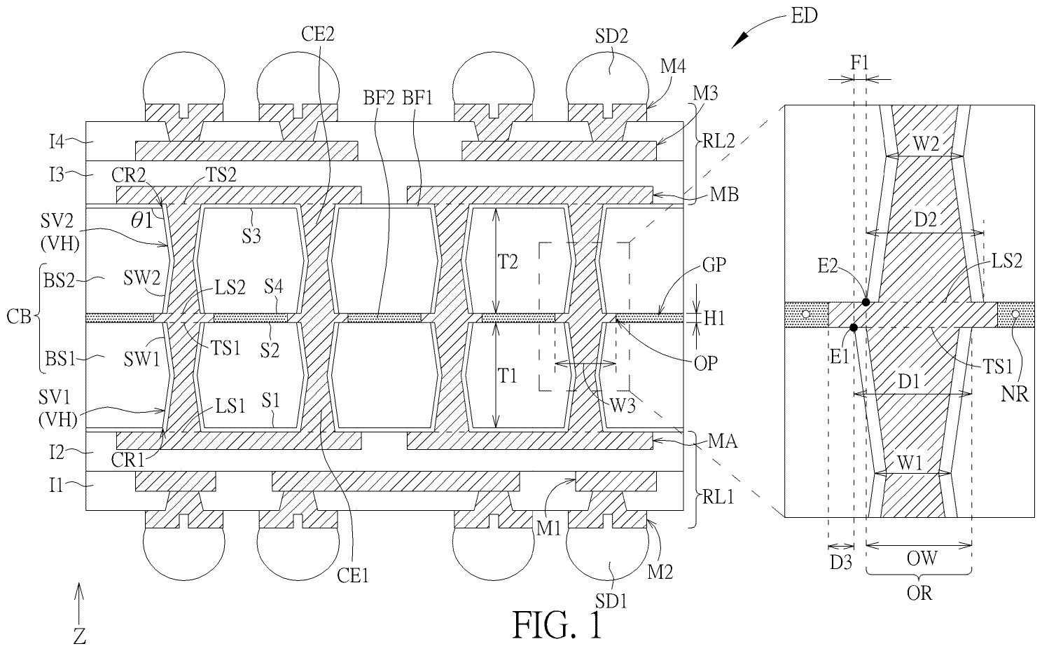

Referring to FIG. 1, FIG. 1 schematically illustrates a cross-sectional view of an electronic device according to a first embodiment of the present disclosure. According to the present embodiment, as shown in FIG. 1, the electronic device ED may include a substrate CB, wherein the substrate CB may include at least two base layers, that is, the first base layer BS1 and the second base layer BS2. The second base layer BS2 is disposed on the first base layer BS1. Specifically, the second base layer BS2 may be bonded to the first base layer BS1 to form the substrate CB. The first base layer BS1 and the second base layer BS2 may include any suitable material that is laser penetrable. For example, the first base layer BS1 and the second base layer BS2 may include glass, ceramic, wafer, organic materials, other suitable materials or combinations of the above-mentioned materials. The material of the first base layer BS1 may be the same as or different from the material of the second base layer BS2.

According to the present embodiment, the first base layer BS1 includes at least one first sub via SV1. For example, FIG. 1 shows the structure in which the first base layer BS1 includes four first sub vias SV1, but not limited thereto. The first sub via SV1 may penetrate the first base layer BS1. In such condition, the first base layer BS1 may include a surface S1 away from the second base layer BS2 (or the bottom surface of the first base layer BS1) and a surface S2 adjacent to the second base layer BS2 (or the top surface of the first base layer BS1), and the first sub via SV1 may connect the surface S1 and the surface S2, or a sidewall of the first sub via SV1 is connected between the surface S1 and the surface S2.

In the present embodiment, the first sub via SV1 may be formed by performing a modification process and an etching process on the first base layer BS1, but not limited thereto. In detail, the first base layer BS1 may be provided at first, and a modification process may be performed on a portion of the first base layer BS1, wherein the portion of the first base layer BS1 corresponds to the predetermined disposition position of the first sub via SV1. In the present embodiment, the modification process for example includes a laser modification process. Specifically, a portion of the first base layer BS1 may be irradiated with laser light to modify the portion of the first base layer BS1. After the modification process, the bonding ability of the modified portion of the first base layer BS1 may be different from (for example, weaker than) the bonding ability of another portion of the first base layer BS1 that is not modified, that is, the structure of the modified portion of the first base layer BS1 may be weakened. In addition, the refractive index of the modified portion of the first base layer BS1 to light may be different from the refractive index of another portion of the first base layer BS1 that is not modified to light, but not limited thereto. After the modification process, an etching process may be performed on the first base layer BS1. The etching process may include dry etching or wet etching, and wet etching may include acid etching, alkali etching or a combination thereof, which is not limited in the present embodiment. In the etching process, the modified portion of the first base layer BS1 may be removed, thereby forming the first sub via SV1 penetrating the first base layer BS1.

When performing an etching process on the first base layer BS1, different etching rates may be obtained at different positions of the first base layer BS1, but not limited thereto. Specifically, the etching rate at the surface of the first base layer BS1 may be greater than the etching rate at the center of the first base layer BS1. In such condition, the formed sidewall SW1 of the first sub via SV1 may gradually shrink from the surface of the first base layer BS1 (such as the surface S1 or the surface S2) to the center of the first base layer BS1. That is, the width of the first sub via SV1 may gradually become smaller from the surface of the first base layer BS1 to the center of the first base layer BS1 or a position adjacent to the center of the first base layer BS1. In the present embodiment, the minimum width of the first sub via SV1 may correspond to any suitable position where a distance between the surface (such as the surface S1 or the surface S2) of the first base layer BS1 and the position is 40% to 60% of the thickness (may substantially be the same as the depth T1 of the first sub via SV1) of the first base layer BS1. For example, as shown in FIG. 1, in a cross-sectional view of the electronic device ED, the first sub via SV1 may have an hourglass shape and have a maximum width D1 and a minimum width W1, wherein a ratio of the minimum width W1 to the maximum width D1 may be greater than or equal to 0.8 and less than or equal to 1 (that is, 0.8≤W1/D1≤1). The maximum width D1 of the first sub via SV1 may for example be the width of the top side TS1 (that is, the side adjacent to the surface S2) or the bottom side LS1 (that is, the side adjacent to the surface S1) of the first sub via SV1. The minimum width W1 of the first sub via SV1 may for example be the width of the first sub via SV1 at a position adjacent to the center of the first base layer BS1. In some embodiments, from the surface of the first base layer BS1 to the center of the first base layer BS1, the width change of the first sub via SV1 may be linear, as shown in FIG. 1. In such condition, in the cross-sectional view of the electronic device ED, the sidewall SW1 may have linear feature. In some embodiments, from the surface of the first base layer BS1 to the center of the first base layer BS1, the width change of the first sub via SV1 may not be linear. In such condition, the sidewall SW1 may have curved feature. In the present embodiment, the maximum width D1 may range from 30 micrometers (μm) to 150 μm (that is, 30 μm≤D1≤150 μm), but not limited thereto. In some embodiments, the maximum width D1 may range from 40 μm to 100μm (that is, 40 μm≤D1≤100 μm). In some embodiments, the maximum width D1 may range from 50 μm to 80 μm (that is, 50 μm≤D1≤80 μm). In addition, in the present embodiment, a difference between the maximum width D1 and the minimum width W1 may range from 0.01 μm to 50 μm (that is, 0.01 μm≤D1−W1≤50 μm), but not limited thereto. In some embodiments, the difference between the maximum width D1 and the minimum width W1 may range from 0.02 μm to 45 μm (that is, 0.02 μm≤D1−W1≤45 ∥m). In some embodiments, the difference between the maximum width D1 and the minimum width W1 may range from 0.03 μm to 40 μm (that is, 0.03 μm≤D1−W1≤40 μm). Moreover, in the present embodiment, the first sub via SV1 may have a depth T1, wherein the depth T1 may range from 20 μm to 400 μm (that is, 20 μm≤T1≤400 μm), but not limited thereto. In some embodiments, the depth T1 may range from 100 μm to 375 μm (that is, 100 μm≤T1≤375 μm). In some embodiments, the depth T1 may range from 250 μm to 350 μm (that is, 250 μm≤T1≤350 μm). The depth T1 may for example be defined as the vertical distance between the bottom side LS1 and the top side TS1 of the first sub via SV1. The depth T1 may substantially be the same as the thickness of the first base layer BS1. Therefore, in some embodiments, the depth T1 may also be the vertical distance between the surface S1 and the surface S2. By controlling the size of the first sub via SV1 (including the above-mentioned maximum width D1, minimum width W1 and depth T1), when the conductive material (that is, the first conductive element CE1) is disposed in the first sub via SV1 in subsequent process, the situation that the difficulty of the process is increased due to excessively high aspect ratio of the first sub via SV1 may reduce. For example, in the present embodiment, the depth T1 and maximum width D1 of the first sub via SV1 may be designed, such that the aspect ratio of the first sub via SV1 is less than or equal to 10, but not limited thereto.

According to the present embodiment, the second base layer BS2 includes at least one second sub via SV2, wherein the second sub via SV2 may penetrate the second base layer BS2. That is, the second base layer BS2 may include a surface S3 away from the first base layer BS1 (or the top surface of the second base layer BS2) and a surface S4 adjacent to the first base layer BS1 (or the bottom surface of the second base layer BS2), and the second sub via SV2 may connect the surface S3 and the surface S4. The forming method of the second sub via SV2 may refer to the forming method of the first sub via SV1 mentioned above, and will not be redundantly described. In such condition, the second sub via SV2 may have a maximum width D2, a minimum width W2 and a depth T2. The maximum width D2 may for example be the width of the top side TS2 (that is, the side adjacent to the surface S3) or the bottom side LS2 (that is, the side adjacent to the surface S4) of the second sub via SV2. The minimum width W2 may be the width of the second sub via SV2 at a position adjacent to the center of the second base layer BS2. The depth T2 may be the vertical distance between the bottom side LS2 and the top side TS2 of the second sub via SV2. The depth T2 may substantially be the same as the thickness of the second base layer BS2. Therefore, in some embodiments, the depth T2 may also be the vertical distance between the surface S3 and the surface S4. The ranges of the maximum width D2, minimum width W2 and depth T2 may respectively refer to the ranges of the maximum width D1, minimum width W1 and depth T1 of the first sub via SV1 mentioned above, and will not be redundantly described. In addition, the feature of the sidewall SW2 of the second sub via SV2 may refer to the feature of the sidewall SW1 of the first sub via SV1 mentioned above, and will not be redundantly described.

According to the present embodiment, the first base layer BS1 and the second base layer BS2 may be bonded to each other in the way that the first sub via SV1 corresponds to the second sub via SV2. In detail, after the first base layer BS1 and the second base layer BS2 are bonded to form the substrate CB, one of the first sub vias SV1 in the first base layer BS1 may correspond to one of the second sub vias SV2 in the second base layer BS2. That is, in the normal direction of the electronic device ED (that is, the direction Z, which will not be redundantly described in the following), the first sub via SV1 may overlap the second sub via SV2. In such condition, the number of the first sub vias SV1 in the first base layer BS1 may be the same as the number of the second sub vias SV2 in the second base layer BS2, or the distribution of the first sub vias SV1 in the first base layer BS1 may be the same as the distribution of the second sub vias SV2 in the second base layer BS2. In the present embodiment, a first sub via SV1 and a second sub via SV2 overlapped with the first sub via SV1 may define a via VH. That is, the via VH may include a first sub via SV1 and a second sub via SV2 which are overlapped with each other. In other words, the substrate CB of the electronic device ED may include at least one via VH to form a substrate structure, wherein the via VH is defined by overlapping the first sub via SV1 in the first base layer BS1 and the second sub via SV2 in the second base layer BS2. In such condition, the via VH may penetrate the first base layer BS1 and the second base layer BS2. In addition, the via VH may connect the surface S1 of the first base layer BS1 away from the second base layer BS2 and the surface S3 of the second base layer BS2 away from the first base layer BS1.

According to the present embodiment, in a via VH, the first sub via SV1 may be offset from the second sub via SV2, and an offset distance F1 may be included between the first sub via SV1 and the second sub via SV2, but not limited thereto. In the cross-sectional view of the electronic device ED, the offset distance F1 may be defined as the distance between an end (such as the end E1) of the top side TS1 (or the side adjacent to the second sub via SV2) of the first sub via SV1 and a corresponding end (such as the end E2) of the bottom side LS2 (or the side adjacent to the first sub via SV1) of the second sub via SV2 in a direction perpendicular to the normal direction of the electronic device ED. The offset distance F1 may be determined according to the degree of overlap between the first sub via SV1 and the second sub via SV2. Specifically, in the present embodiment, the first sub via SV1 and the second sub via SV2 in a via VH may have an overlapping region OR. In some embodiments, in the cross-sectional view of the electronic device ED (for example, FIG. 1), the region to which the portion of the top side TS1 (or the side adjacent to the second sub via SV2) of the first sub via SV1 and the portion of the bottom side LS2 (or the side adjacent to the first sub via SV1) of the second sub via SV2 which are overlapped with each other correspond may be defined as the overlapping region OR of the first sub via SV1 and the second sub via SV2, but not limited thereto. In some embodiments, in the top view of the electronic device ED, the region to which the portion of the pattern of the top side TS1 (or the side adjacent to the second sub via SV2) of the first sub via SV1 and the portion of the pattern of the bottom side LS2 (or the side adjacent to the first sub via SV1) of the second sub via SV2 which are overlapped with each other correspond may be defined as the overlapping region OR of the first sub via SV1 and the second sub via SV2. In other words, the overlapping region OR may correspond to the first sub via SV1 and the second sub via SV2 at the same time. When the size of the overlapping region OR is greater, the degree of overlap of the first sub via SV1 and the second sub via SV2 is greater, and the offset distance F1 may be lower. In the present embodiment, as shown in FIG. 1, the overlapping region OR may have an overlapping width OW, and the first sub via SV1 may have a pore size, wherein a difference between the pore size and the overlapping width OW may range from 0.01 μm to 5 μm, but not limited thereto. The pore size of the first sub via SV1 described herein may be defined as the maximum width of the first sub via SV1, that is, the maximum width D1 mentioned above. In other words, a difference between the maximum width D1 and the overlapping width OW may range from 0.01 μm to 5 μm (that is, 0.01 μm≤D1−OW≤5 μm). It should be noted that as shown in FIG. 1, the offset distance F1 is the difference between the maximum width D1 and the overlapping width OW (that is, F1=D1−OW). In such condition, the range of the difference between the maximum width D1 and the overlapping width OW mentioned above may be the range of the offset distance F1. In some embodiments, the difference between the maximum width D1 and the overlapping width OW (or the offset distance F1) may range from 0.03 μm to 2.5 μm (that is, 0.03 μm≤D1−OW≤2.5 μm). In some embodiments, the difference between the maximum width D1 and the overlapping width OW may range from 0.05 μm to 2 μm (that is, 0.05 μm≤D1−OW≤2 μm). In some embodiments, the overlapping width OW may range from 0.5 times the maximum width D1 to the maximum width D1 (that is, 0.5D1≤OW≤D1). In some embodiments, the overlapping width OW may range from 0.6 times the maximum width D1 to the maximum width D1 (that is, 0.6D1≤OW≤D1). In some embodiments, the overlapping width OW may range from 0.7 times the maximum width D1 to the maximum width D1 (that is, 0.7D1≤OW≤D1). It should be noted that the range of the difference between the overlapping width OW and the pore size of the second sub via SV2 may refer to the range of the difference between the maximum width D1 and the overlapping width OW mentioned above, wherein the pore size of the second sub via SV2 may be defined as the maximum width of the second sub via SV2, that is, the maximum width D2 mentioned above. In addition, the offset distance F1 may also be the difference between the maximum width D2 of the second sub via SV2 and the overlapping width OW. By controlling the offset distance F1 of the first sub via SV1 and the second sub via SV2 in the above-mentioned range, the possibility of poor contact between the conductive materials (that is, the first conductive element CE1 and the second conductive element CE2) subsequently disposed in the first sub via SV1 and the second sub via SV2 may be reduced. It should be noted that in some embodiments, the first sub via SV1 may not be offset from the second sub via SV2, that is, the offset distance F1 may be 0.

According to the present embodiment, the electronic device ED may further include a first buffer layer BF1 disposed on a surface of the first base layer BS1 and on a surface of the second base layer BS2. Specifically, the first buffer layer BF1 may at least cover the corner CR1 between the surface S1 of the first base layer BS1 away from the second base layer BS2 and the sidewall SW1 of the first sub via SV1 and the corner CR2 between the surface S3 of the second base layer BS2 away from the first base layer BS1 and the sidewall SW2 of the second sub via SV2. The corner CR1 and the corner CR2 may include chamfers, arc angles or right angles. The corner CR1 and the corner CR2 may correspond to an included angle θ1 located between 90 degrees to 130 degrees. Therefore, the possibility of breakage of the conductive materials (that is, the first conductive element CE1 and the second conductive element CE2) subsequently disposed may be reduced. That is, the first buffer layer BF1 may be disposed in at least a portion of the via VH. For example, in the present embodiment, the first buffer layer BF1 may be disposed on the surface S1 and the side surface (that is, the sidewall SW1 of the first sub via SV1) of the first base layer BS1 and completely cover the sidewall SW1, but not limited thereto. In some embodiments, the first buffer layer BF1 may expose a portion of the sidewall SW1 adjacent to the second base layer BS2. Similarly, in the present embodiment, the first buffer layer BF1 may be disposed on the surface S3 and the side surface (that is, the sidewall SW2 of the second sub via SV2) of the second base layer BS2 and completely cover the sidewall SW2, but not limited thereto. In some embodiments, the first buffer layer BF1 may expose a portion of the sidewall SW2 adjacent to the first base layer BS1. In the present embodiment, the first buffer layer BF1 may not be disposed on the surface S2 of the first base layer BS1 adjacent to the second base layer BS2 and the surface S4 of the second base layer BS2 adjacent to the first base layer BS1. That is, the first buffer layer BF1 may not be disposed between the first base layer BS1 and the second base layer BS2. The first buffer layer BF1 may include the material with the toughness ranges from 0.1-100KJ/m². The first buffer layer BF1 may include any suitable organic insulating material or inorganic insulating material, such as polyimide (PI), parylene, benzocyclobutene (BCB), epoxy resin, polycarbonate (PC), polyethylene terephthalate (PET), polyethylene naphthalate (PEN), silicon oxide, silicon nitride, silicon oxynitride, compounds of titanium or combinations of the above-mentioned materials, but not limited thereto. In the present embodiment, the thickness of the first buffer layer BF1 may range from 0. 01 μm to 10 μm (that is, 0. 01 μm≤thickness≤10 μm), but not limited thereto. In some embodiments, the thickness of the first buffer layer BF1 may range from 0.05 μm to 8 μm (that is, 0.05 μm≤thickness≤8 μm). In some embodiments, the thickness of the first buffer layer BF1 may range from 0.1 μm to 6 μm (that is, 0.1 μm≤thickness≤6 μm). In addition, a ratio of the thickness of the first buffer layer BF1 to the pore size of the first sub via SV1 (that is, the maximum width D1) or the pore size of the second sub via SV2 (that is, the maximum width D2) may range from 0.02 to 0.2 (that is, 0.02≤ratio≤0.2), but not limited thereto. Through the size design of the first buffer layer BF1 mentioned above, the influence of the first buffer layer BF1 on the subsequent manufacturing processes of the first conductive element CE1 and the second conductive element CE2 may be reduced. According to some embodiments, the first buffer layer BF1 may include a single layer structure or a multi-layer structure, wherein the layers in the multi-layer structure may have the same material or different materials.

According to the present embodiment, the electronic device ED may further include the first conductive element CE1 and the second conductive element CE2, wherein the first conductive element CE1 is disposed in the first sub via SV1, and the second conductive element CE2 is disposed in the second sub via SV2. Specifically, after the first sub via SV1 is formed in the first base layer BS1 and the first buffer layer BF1 is disposed on the sidewall SW1 of the first sub via SV1, the first conductive element CE1 may be filled into the first sub via SV1. The first conductive element CE1 may fully fill the first sub via SV1, but not limited thereto. Similarly, after the second sub via SV2 is formed in the second base layer BS2 and the first buffer layer BF1 is disposed on the sidewall SW2 of the second sub via SV2, the second conductive element CE2 may be filled into the second sub via SV2. The second conductive element CE2 may fully fill the second sub via SV2, but not limited thereto. A portion of the first conductive element CE1 and a portion of the second conductive element CE2 may further be located in a gap GP between the first base layer BS1 and the second base layer BS2. Specifically, the electronic device ED may further include a gap GP located between the first base layer BS1 and the second base layer BS2. In some embodiments, the gap GP may be formed due to other layers (such as the second buffer layer BF2) included between the first base layer BS1 and the second base layer BS2. In some embodiments, the gap GP may be formed because the surface S2 of the first base layer BS1 and the surface S4 of the second base layer BS2 include rough surfaces. A portion of the first conductive element CE1 and a portion of the second conductive element CE2 may be located in the gap GP, wherein the portion of the first conductive element CE1 and the portion of the second conductive element CE2 may contact each other. In such condition, the first conductive element CE1 may contact the second conductive element CE2, thereby being electrically connected to the second conductive element CE2. Specifically, in the present embodiment, after the first conductive element CE1 is disposed in the first sub via SV1 of the first base layer BS1, the second conductive element CE2 is disposed in the second sub via SV2 of the second base layer BS2, and the first base layer BS1 and the second base layer BS2 are bonded to form the substrate CB, a heating process may be performed on the substrate CB. In such condition, the first conductive element CE1 and the second conductive element CE2 may be heated and expand to protrude from the first sub via SV1 and the second sub via SV2 respectively, thereby being contacted with each other in the gap GP. According to the present embodiment, the gap GP may have a thickness H1, wherein the thickness H1 may be less than or equal to 3 μm (that is, H1≤3 μm). In other words, the surface roughness of the surface S2 of the first base layer BS1 and the surface roughness of the surface S4 of the second base layer BS2 may be less than or equal to 3 μm, but not limited thereto. In some embodiments, the thickness H1 may range from 0.1 nanometers (nm) to 1 μm (that is, 0.1 nm≤H1≤1 μm). In some embodiments, the thickness H1 may range from 0.1 nm to 20 nm (that is, 0.1 nm≤H1≤20 nm). The thickness H1 may be defined as the maximum thickness of the gap GP, but not limited thereto. Through the design of the thickness H1 of the gap GP mentioned above, the possibility that the first conductive element CE1 and the second conductive element CE2 are not easily contacted with each other due to the excessively large thickness H1 may be reduced. The first conductive element CE1 and the second conductive element CE2 may include metal materials, but not limited thereto. For example, the first conductive element CE1 and the second conductive element CE2 may include copper (Cu), aluminum (Al), other suitable metals or combinations of the above-mentioned materials. It should be noted that the gap GP, the bonding position of the base layers or the bonding position of the first conductive element CE1 and the second conductive element CE2 may have bubbles or non-fully-filled regions NR, wherein the maximum size of the bubble or the non-fully-filled region NR may be less than or equal to 1 μm. The maximum size of the bubble or the non-fully-filled region NR described herein may for example be the maximum width or the diameter of the bubble or the non-fully-filled region NR, but not limited thereto. Therefore, the influence of bubbles on the electrical connection between the first conductive element CE1 and the second conductive element CE2 may be reduced. According to some embodiments, a surface treatment may be performed on at least one surface of the first base layer BS1 and at least one surface of the second base layer BS2, or a surface treatment may be performed on a local area of the surface of the first base layer BS1 and a local area of the surface of the second base layer BS2 to roughen the surfaces. The bonding strength of the base layers and other layers may be improved through the step of surface treatment. The surface treatment may include laser, etching, plasma treatment, combinations of the above-mentioned methods or other suitable methods.

According to the present embodiment, the electronic device ED may further include a second buffer layer BF2 disposed between the first base layer BS1 and the second base layer BS2, but not limited thereto. The second buffer layer BF2 may be used to bond the first base layer BS1 and the second base layer BS2. Specifically, in some embodiments, before bonding the first base layer BS1 and the second base layer BS2, the second buffer layer BF2 may be disposed on the surface S2 of the first base layer BS1 used for bonding with the second base layer BS2, and then the first base layer BS1 may be bonded to the second base layer BS2 through the second buffer layer BF2. In some embodiments, the second buffer layer BF2 may be disposed on the surface S4 of the second base layer BS2 used for bonding with the first base layer BS1 at first, and then the first base layer BS1 may be bonded to the second base layer BS2 through the second buffer layer BF2. In some embodiments, the second buffer layer BF2 may be disposed on the surface S2 of the first base layer BS1 and the surface S4 of the second base layer BS2 at the same time. In some embodiments, the electronic device ED may not include the second buffer layer BF2. In such condition, the second buffer layer BF2 may include a portion of the first base layer BS1 and a portion of the second base layer BS2, that is, the first base layer BS1 may contact the second base layer BS2. In other words, the first base layer BS1 and the second base layer BS2 may be bonded to each other by providing appropriate temperature, appropriate pressure or through other suitable processes. The disposition situation of the second buffer layer BF2 mentioned above may be determined according to the materials of the first base layer BS1, the second base layer BS2 and the second buffer layer BF2. Specifically, when the materials of the first base layer BS1 and the second base layer BS2 are easily bonded to each other, the second buffer layer BF2 is not needed; when the materials of the first base layer BS1 and the second base layer BS2 are not easily bonded to each other, the first base layer BS1 and the second base layer BS2 may be bonded to each other through disposition of the second buffer layer BF2. The first buffer layer BF1 may not contact the second buffer layer BF2. The thickness of the second buffer layer BF2 may range from 0.1 nm to 20 nm (that is, 0.1 nm≤thickness≤20 nm), but not limited thereto. In some embodiments, the thickness of the second buffer layer BF2 may range from 0.1 nm to 15 nm (that is, 0.1 nm≤thickness≤15 nm). In some embodiments, the thickness of the second buffer layer BF2 may range from 0.1 nm to 10 nm (that is, 0.1 nm≤thickness≤10 nm). The second buffer layer BF2 may include any suitable material having the dielectric loss (Df) of 0.0001-0.01 at 10 MHz. Specifically, the second buffer layer BF2 may include any suitable organic insulating material or inorganic insulating material that meets the above-mentioned conditions. For example, the second buffer layer BF2 may include silicon oxide, silicon nitride, silicon oxynitride, polymers, silicon-containing oxides, nitride materials or combinations thereof, but not limited thereto.

According to the present embodiment, as shown in FIG. 1, the second buffer layer BF2 may have an opening OP, wherein the opening OP may expose the first sub via SV1 and the second sub via SV2. Specifically, in the normal direction of the electronic device ED, the opening OP may overlap the first sub via SV1 and the second sub via SV2. In other words, the opening OP may expose the first conductive element CE1 disposed in the first sub via SV1 and the second conductive element CE2 disposed in the second sub via SV2, such that the first conductive element CE1 and the second conductive element CE2 may contact each other in the opening OP. The opening OP may have a width W3, wherein the width W3 may be greater than or equal to the pore size of the first sub via SV1 (that is, the maximum width D1) and/or the pore size of the second sub via SV2 (that is, the maximum width D2). Therefore, in the top view of the electronic device ED, the projection of the first sub via SV1 and/or the second sub via SV2 may be located in the range of the opening OP. A difference between the width W3 and the maximum width D1 (or the maximum width D2) may range from 0.03 μm to 3 μm (that is, 0.03 μm≤W3−D1≤3 μm), but not limited thereto. When the difference between the width W3 and the maximum width D1 (or the maximum width D2) is too small, poor contact between the first conductive element CE1 and the second conductive element CE2 may occur due to the misalignment of the first sub via SV1 and the second sub via SV2. When the difference between the width W3 and the maximum width D1 (or the maximum width D2) is too large, it may affect the bonding between the first conductive element CE1 and the second conductive element CE2 or affect the bonding effect of the second buffer layer BF2, thereby affecting the reliability of electronic device.

According to the present embodiment, the electronic device ED may further include a first redistribution layer RL1 and a second redistribution layer RL2, wherein the first redistribution layer RL1 is disposed at a side of the first base layer BS1 opposite to the second base layer BS2, and the second redistribution layer RL2 is disposed at a side of the second base layer BS2 opposite to the first base layer BS1. That is, the substrate CB may be located between the first redistribution layer RL1 and the second redistribution layer RL2. In the present embodiment, the redistribution layer may be the layer capable of adjusting the positions of the signal input terminal and the signal output terminal or adjusting the layout of wires. In other words, the circuits may be extended to have a greater spacing through the redistribution layer, or a circuit may be redistributed to another circuit with different spacing. Therefore, the circuit may be redistributed, and/or the fan out area of the circuit may increase. The redistribution layer may include a stacked structure formed by stacking at least one insulating layer and at least one conductive layer, wherein the stacking direction of the insulating layer(s) and the conductive layer(s) may for example parallel to the normal direction of the electronic device ED. Specifically, as shown in FIG. 1, the first redistribution layer RL1 may include an insulating layer I1, an insulating layer I2, a conductive layer M1, a conductive layer M2 and a conductive layer MA, but not limited thereto. The insulating layer 12 is located below the first conductive element CE1, and the insulating layer I1 is located below the insulating layer 12. The conductive layer M1 is located between the insulating layer I1 and the insulating layer 12. The conductive layer M2 is located below the insulating layer I1 and may contact the conductive layer M1 through the via (not labeled) in the insulating layer I1, thereby being electrically connected to the conductive layer M1. The conductive layer MA is located between the insulating layer 12 and the first conductive element CE1 and may contact the first conductive element CE1 to be electrically connected to the first conductive element CE1. The conductive layer M2 may be an under bump metal layer, but not limited thereto. It should be noted that although it is not shown in figure, the conductive layer in the first redistribution layer RL1 may be electrically connected to the first conductive element CE1, thereby electrically connecting the first conductive element CE1 to the conductive layer M2. For example, the conductive layer M1 may contact the conductive layer MA through the via (not shown) in the insulating layer I2, thereby being electrically connected to the first conductive element CE1. Similarly, the second redistribution layer RL2 may include an insulating layer I3, an insulating layer I4, a conductive layer M3, a conductive layer M4 and a conductive layer MB, but not limited thereto. The insulating layer I3 is located on the first conductive element CE1, and the insulating layer I4 is located on the insulating layer I3. The conductive layer M3 is located between the insulating layer I3 and the insulating layer I4. The conductive layer M4 is located on the insulating layer I4 and may contact the conductive layer M3 through the via (not labeled) in the insulating layer I4, thereby being electrically connected to the conductive layer M3. The conductive layer MB is located between the insulating layer I3 and the second conductive element CE2 and may contact the second conductive element CE2 to be electrically connected to the second conductive element CE2. The conductive layer M4 may be an under bump metal layer, but not limited thereto. It should be noted that although it is not shown in figure, the conductive layer in the second redistribution layer RL2 may be electrically connected to the second conductive element CE2, thereby electrically connecting the second conductive element CE2 to the conductive layer M4. For example, the conductive layer M3 may contact the conductive layer MB through the via (not shown) in the insulating layer I3, thereby being electrically connected to the second conductive element CE2. The conductive layer M1, the conductive layer M2, the conductive layer M3, the conductive layer M4, the conductive layer MA and the conductive layer MB may include any suitable conductive material, such as metal materials, but not limited thereto. The insulating layer I1, the insulating layer I2, the insulating layer I3 and the insulating layer I4 may include any suitable insulating material, such as photosensitive polyimide (PSPI), Ajinomoto build-up film (ABF) material, glass, combinations of the above-mentioned materials or other suitable materials. The first redistribution layer RL1 and the second redistribution layer RL2 may respectively be electrically connected to suitable electronic elements. Specifically, the electronic device ED may further include a solder ball SD1 located below the conductive layer M2 and a solder ball SD2 located on the conductive layer M4, wherein the first redistribution layer RL1 may be bonded to other electronic elements through the solder ball SD1, and the second redistribution layer RL2 may be bonded to other electronic elements through the solder ball SD2. In such condition, the electronic element bonded to the second redistribution layer RL2 through the solder ball SD2 may be electrically connected to the electronic element bonded to the first redistribution layer RL1 through the solder ball SD1 through the second redistribution layer RL2, the second conductive element CE2, the first conductive element CE1 and the first redistribution layer RL1. It should be noted that the structure of the redistribution layer shown in FIG. 1 is exemplary, it is not limited in the present disclosure. In other words, two sides of the substrate CB may carry redistributions layers to form a circuit structure, wherein the substrate CB may be regarded as the interposer, but not limited thereto.

According to the present embodiment, the via VH in the substrate CB is defined by the first sub via SV1 and the second sub via SV2 whose aspect ratio is lower than the aspect ratio of the via VH, wherein the two portions of the conductive element in the via VH (that is, the first conductive element CE1 and the second conductive element CE2) may respectively be disposed in the first sub via SV1 and the second sub via SV2 at first, and then the two portions of the conductive element may contact each other after bonding the first base layer BS1 and the second base layer BS2 (for example, through a hybrid bonding of Cu—Cu). Therefore, the difficulty of the manufacturing process of the conductive element in the via VH may be reduced. Specifically, since the aspect ratio of the first sub via SV1 and the second sub via SV2 may be lower than the aspect ratio of the via VH, the conductive elements may be easily disposed (or filled) in the first sub via SV1 and the second sub via SV2. In other words, through the above-mentioned method, the substrate CB having the via VH with a high aspect ratio may be formed while reducing the process difficulty of the first conductive element CE1 and the second conductive element CE2. It should be noted that the electronic device ED of the present embodiment may further include other suitable elements or layers, which is not limited to the structure shown in FIG. 1.

The manufacturing method of the electronic device ED of the present embodiment will be detailed in the following.

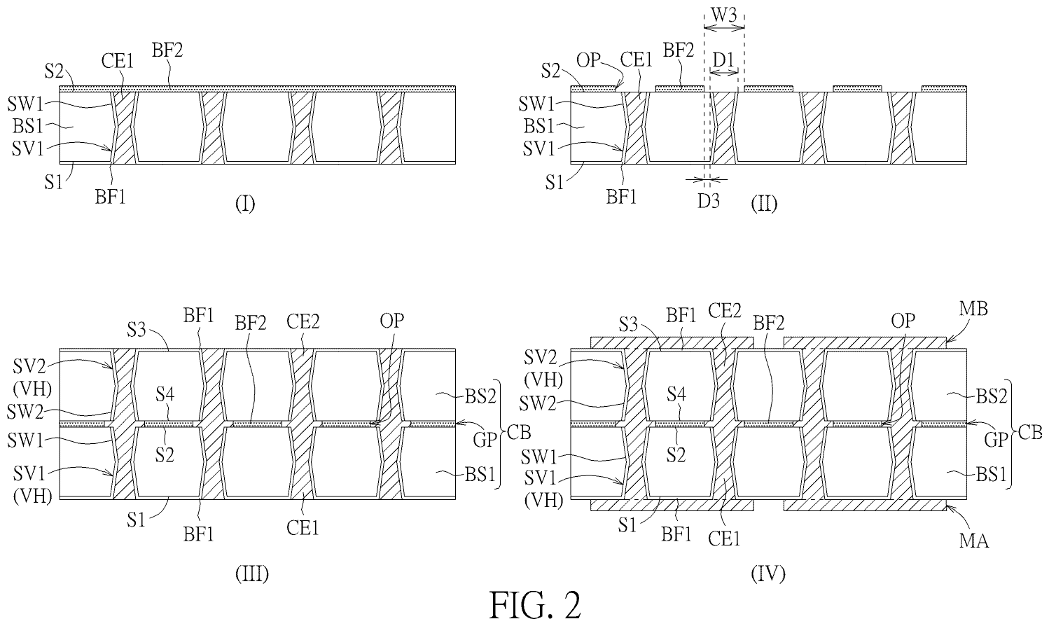

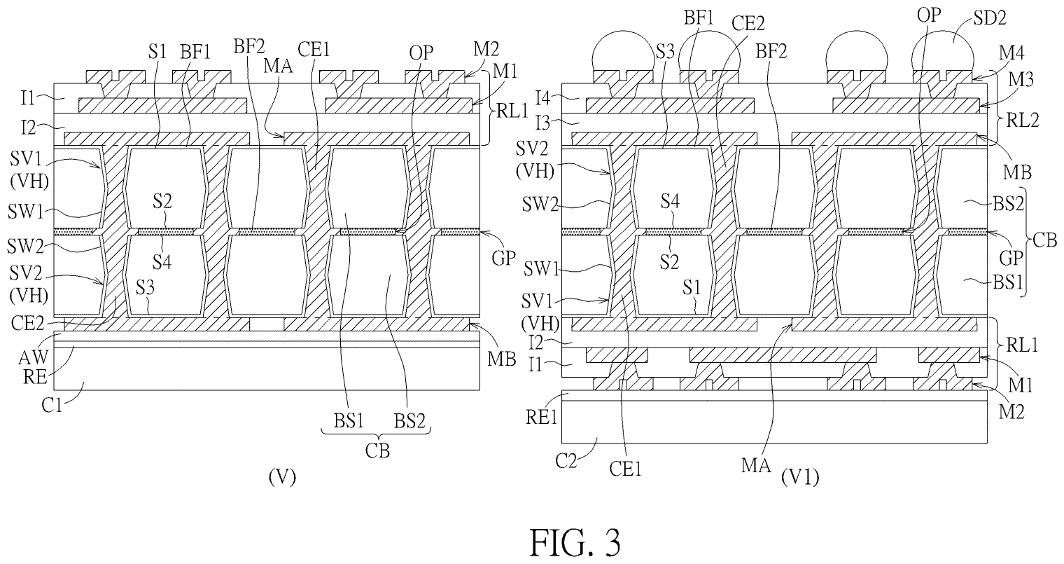

Referring to FIG. 2 and FIG. 3, FIG. 2 to FIG. 3 schematically illustrate a manufacturing process of the electronic device according to the first embodiment of the present disclosure. According to the present embodiment, the manufacturing method M100 of the electronic device ED may include following steps:
S100: providing a first base layer, and forming a first sub via in the first base layer;
S102: disposing a first buffer layer in at least a portion of the first sub via;
S104: disposing a first conductive element in the first sub via;
S106: providing a second base layer, and forming a second sub via in the second base layer;
S108: disposing a first buffer layer in at least a portion of the second sub via;
S110: disposing a second conductive element in the second sub via;
S112: disposing a second buffer layer on a surface of the first base layer, and patterning the second buffer layer to form at least one opening;
S114: bonding the first base layer and the second base layer to form a substrate;
S116: disposing a first redistribution layer at a side of the first base layer opposite to the second base layer; and
S118: disposing a second redistribution layer at a side of the second base layer opposite to the first base layer.

The detail of the steps in the manufacturing method M100 will be described in the following.

As shown in the structure (I) of FIG. 2, the manufacturing method M100 of the electronic device ED may include the step S100:providing a first base layer BS1, and forming a first sub via SV1 in the first base layer BS1. The forming method of the first sub via SV1 may refer to the contents mentioned above, and will not be redundantly described. After the first sub via SV1 is formed, the manufacturing method M100 may further include the step S104: disposing a first conductive element CE1 in the first sub via SV1. Specifically, the first conductive element CE1 may be provided in the first sub via SV1 through sputtering, electroplating, chemical plating or other suitable processes. It should be noted that although it is not shown in figure, before disposing the conductive elements (including the first conductive element CE1 and the second conductive element CE2) of the electronic device ED, a seed layer SE may be disposed at first, and then the conductive elements may be disposed on the seed layer SE. The conductive element of the electronic device ED may include titanium, tantalum, tungsten, platinum, copper, aluminum, nitride, carbide or combinations thereof, but not limited thereto. For example, in the present embodiment, the seed layer SE may be disposed in the first sub via SV1 at first, and then the first conductive element CE1 may be disposed on the seed layer SE, that is, the seed layer SE is located between the first conductive element CE1 and the first base layer BS1. The forming method of the conductive elements in the following embodiments may refer to the contents above, and will not be redundantly described. It should be noted that in order to simplify the figures, the seed layer SE is not shown in the following figures. It should be noted that in the present embodiment, the manufacturing method M100 may further include the step S102:disposing a first buffer layer BF1 in at least a portion of the first sub via SV1 before disposing the first conductive element CE1 in the first sub via SV1. Specifically, after the first sub via SV1 is formed, the first buffer layer BF1 may be disposed along the sidewall SW1 of the first sub via SV1 at first, and then the first conductive element CE1 is disposed. In such condition, the first conductive element CE1 may contact the surface of the first buffer layer BF1 opposite to the first base layer BS1. In the present embodiment, the first buffer layer BF1 may further be disposed on the surface of the first base layer BS1 that is not used for bonding with the second base layer BS2, but not disposed on the surface S2 of the first base layer BS1 that is used for bonding with the second base layer BS2. It should be noted that in some embodiments, when disposing the first buffer layer BF1, the first buffer layer BF1 may be disposed on the surface S2 of the first base layer BS1 at first, and then the portion of the first buffer layer BF1 on the surface S2 may be removed by grinding or other suitable processes. In some embodiments, the portion of the first conductive element CE1 on the surface S2 may also be removed by grinding or other suitable processes, such that the first conductive element CE1 may be disposed in the first sub via SV1 after the removing process, but not limited thereto.

Similarly, the manufacturing method M100 of the electronic device ED may include the step S106: providing a second base layer BS2, and forming a second sub via SV2 in the second base layer BS2 and the step S110: disposing a second conductive element CE2 in the second sub via SV2. In addition, the manufacturing method M100 further includes the step S108: disposing a first buffer layer BF1 in at least a portion of the second sub via SV2 before disposing the second conductive element CE2 in the second sub via SV2. The detail of the forming methods of the second sub via SV2 and the second conductive element CE2 may refer to the forming methods of the first sub via SV1 and the first conductive element CE1 mentioned above, and will not be redundantly described. The structures of the second base layer BS2 and the second conductive element CE2 may refer to the structure (III) of FIG. 2. It should be noted that the step S100 to the step S104 and the step S106 to the step S110 may be performed in any suitable order or performed at the same time.

The manufacturing method M100 of the electronic device ED may further include the step S112: disposing a second buffer layer BF2 on a surface of the first base layer BS1, and patterning the second buffer layer BF2 to form at least one opening OP. Specifically, as shown in the structure (I) of FIG. 2, before bonding the first base layer BS1 and the second base layer BS2, an entire second buffer layer BF2 may be disposed on the surface S2 of the first base layer BS1 used for bonding with the second base layer BS2 at first, wherein the second buffer layer BF2 may contact the first base layer BS1 and the first conductive element CE1 at this time. After that, as shown in the structure (II) of FIG. 2, a patterning process may be performed on the second buffer layer BF2 to form at least one opening OP in the second buffer layer BF2, wherein the opening OP may overlap the first sub via SV1. The second buffer layer BF2 may be used for bonding the first base layer BS1 and the second base layer BS2, and after the first base layer BS1 is bonded to the second base layer BS2, the opening OP may further overlap the second sub via SV2. It should be noted that in some embodiments, the second buffer layer BF2 may be disposed on the surface S4 of the second base layer BS2 used for bonding with the first base layer BS1. In some embodiments, the second buffer layer BF2 may be disposed on the surface S2 of the first base layer BS1 and the surface S4 of the second base layer BS2 at the same time. In some embodiments, the second buffer layer BF2 is not disposed.

The manufacturing method M100 of the electronic device ED may further include the step S114: bonding the first base layer BS1 and the second base layer BS2 to form a substrate CB. Specifically, as shown in the structure (III) of FIG. 2, the first base layer BS1 and the second base layer BS2 may be bonded with each other in the way that the first sub via SV1 and the second sub via SV2 correspond to each other to form the substrate CB. As mentioned above, after bonding the first base layer BS1 and the second base layer BS2, a heating process may be performed on the substrate CB, such that the first conductive element CE1 and the second conductive element CE2 may expand and enter the gap GP between the first base layer BS1 and the second base layer BS2, thereby being in contacted with each other. In some embodiments, the first base layer BS1 and the second base layer BS2 may be bonded to each other through the second buffer layer BF2. In some embodiments, the first base layer BS1 may be directly bonded to the second base layer BS2 and may contact the second base layer BS2, and therefore, the second buffer layer BF2 may be omitted. As shown in the structure (IV) of FIG. 2, after the substrate CB is formed, the conductive layer MA of the first redistribution layer RL1 may be disposed on the surface S1 of the first base layer BS1, and the conductive layer MB of the second redistribution layer RL2 may be disposed on the surface S3 of the second base layer BS2. It should be noted that the width W3 of the opening OP of the second buffer layer BF2 may be greater than the maximum width D1 of the first sub via SV1. In addition, a distance D3 may be included between a side of the opening OP and an end of the first sub via SV1 adjacent to the side, wherein the distance D3 is located between 20 nm to 1 μm (that is, 20 nm≤D3≤1 μm). Through the above-mentioned design, when a hybrid bonding of Cu—Cu is adopted, it can provide suitable space for the conductive elements to expand, thereby improving the reliability after bonding, but not limited thereto. It should be noted that in the embodiment that the second buffer layer BF2 is disposed on the second base layer BS2, the distance D3 may be the distance between a side of the opening OP and an end of the second sub via SV2 adjacent to the side.

The manufacturing method M100 of the electronic device ED may further include the step S116: disposing a first redistribution layer RL1 at a side of the first base layer BS1 opposite to the second base layer BS2. In detail, as shown in the structure (V) of FIG. 3, after bonding the first base layer BS1 and the second base layer BS2 to form the substrate CB, the substrate CB may be placed on a carrier C1. Specifically, the conductive layer MB may be disposed on the surface S3 at first, and then the substrate CB may be placed on the carrier C1 in the way that the conductive layer MB faces the carrier C1. That is, the first base layer BS1 may be away from the carrier C1, or the second base layer BS2 is located between the first base layer BS1 and the carrier C1. After that, the conductive layer MA is disposed on the first base layer BS1 (also shown in the structure (IV) of FIG. 2), the insulating layer I2 is disposed on the conductive layer MA, the patterned conductive layer M1 is disposed on the insulating layer I2, the insulating layer I1 covering the conductive layer M1 is disposed on the insulating layer I2, the via(s) is formed in the insulating layer I1, and the conductive layer M2 filled into the via(s) of the insulating layer Il and in contact with the conductive layer M1 is formed, thereby forming the first redistribution layer RL1, but not limited thereto. Although it is not shown in the figure, the above-mentioned manufacturing process of the first redistribution layer RL1 may further include forming via(s) in the insulating layer I2, such that the conductive layer M1 may be filled into the via(s) in the insulating layer I2 and contact the conductive layer MA. The formation or patterning process of the conductive layers and the insulating layers: first redistribution layer RL1 mentioned above may for example be completed by photolithography, etching, surface treatment, laser, electroplating, and the like, but not limited thereto. In further, by performing surface treatment on at least portion of the regions of the conductive layers and the insulating layers, the surfaces of the conductive layers and the surfaces of the insulating layers may be roughened, thereby improving the bonding strength between the layers. In addition, the first redistribution layer RL1 may include other suitable structures, which is not limited to the structure shown in FIG. 3. The carrier C1 may include any suitable material that can provide support to the substrate CB, such as glass, steel plate, BT plate, and the like. In the present embodiment, a release layer RE and an anti-warpage layer AW may be included between the substrate CB and the carrier C1, wherein the release layer RE is disposed on the carrier C1, and the anti-warpage layer AW may be disposed at least a side of the carrier C1. The anti-warpage layer AW may include any suitable organic material or inorganic material that can control stress. Through the disposition of the anti-warpage layer AW, the possibility of warpage of the substrate CB due to uneven stress on both sides of the substrate CB may be reduced.

The manufacturing method M100 of the electronic device ED further includes the step S118: disposing a second redistribution layer RL2 at a side of the second base layer BS2 opposite to the first base layer BS1. Specifically, as shown in the structure (V) of FIG. 3, after the first redistribution layer RL1 is disposed, the substrate CB may be separated from the carrier C1 by removing the release layer RE. After that, as shown in the structure (VI) of FIG. 3, the substrate CB may be fixed on a carrier C2 through a release layer RE1. Specifically, the substrate CB may be disposed on the carrier C2 in the way that the first conductive element CE1 faces the carrier C2. That is, the second base layer BS2 may be away from the carrier C2. After that, the insulating layer I3 is disposed on the second base layer BS2, the patterned conductive layer M3 is disposed on the insulating layer I3, the insulating layer I4 covering the conductive layer M3 is disposed on the insulating layer I3, the via(s) is formed in the insulating layer I4, and the conductive layer M4 filled into the via(s) of the insulating layer I4 and in contact with the conductive layer M3 may be formed, thereby forming the second redistribution layer RL2, but not limited thereto. The forming method of the second redistribution layer RL2 may refer to the forming method of the first redistribution layer RL1 mentioned above, and will not be redundantly described. In other words, in the manufacturing method M100 of the electronic device ED, the conductive layer MB of the second redistribution layer RL2 may be formed at first, then the first redistribution layer RL1 may be formed, and then other layers in the second redistribution layer RL2 except the conductive layer MB may be provided, but not limited thereto. As shown in the structure (VI) of FIG. 3, after the second redistribution layer RL2 is disposed, the solder ball SD2 may be disposed on the conductive layer M4. After that, the substrate CB may be separated from the carrier C2 by removing the release layer RE1, the substrate CB may be flipped, and the solder ball SD1 may be disposed on the conductive layer M2, thereby forming the electronic device ED shown in FIG. 1. It should be noted that the step S116 and the step S118 may be performed in any suitable order. For example, in some embodiments, the second redistribution layer RL2 may be disposed at first, and then the first redistribution layer RL1 is disposed. According to some embodiments, after the first redistribution layer RL1 and the second redistribution layer RL2 are disposed, a cutting step may be performed. According to some embodiments, a plurality of substrate units separated from each other may be obtained by cutting from the redistribution layer at a side to the redistribution layer at another side. According to some embodiments, after the first redistribution layer RL1 and the second redistribution layer RL2 are disposed, a cutting step may be performed, wherein the cutting step includes cutting the first redistribution layer RL1 and the second redistribution layer RL2 at the same time, and then cutting the substrate CB to obtain the plurality of substrate units separated from each other.

It should be noted that the electronic device ED and the manufacturing method thereof shown in FIG. 1 to FIG. 3 are exemplary, it is not limited in the present embodiment. The electronic device ED may further include other suitable layers or elements, and the manufacturing method of the electronic device ED may thus include other suitable steps. Other embodiments of the present disclosure will be described in the following. In order to simplify the description, the same elements or layers in the following embodiments would be labeled with the same symbol, and the features thereof will not be redundantly described. The differences between the embodiments will be detailed in the following.

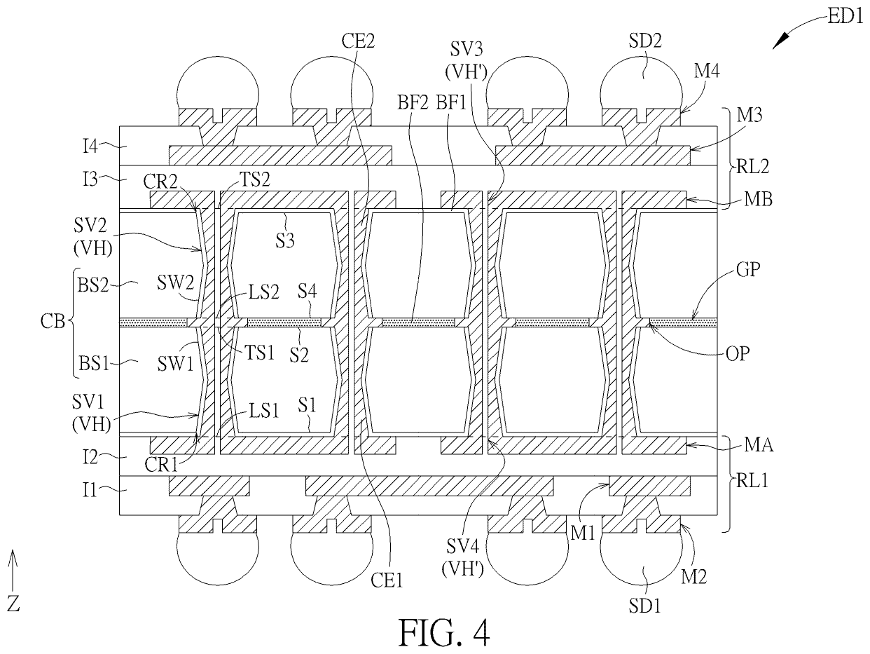

Referring to FIG. 4, FIG. 4 schematically illustrates a cross-sectional view of an electronic device according to a second embodiment of the present disclosure. Compared with the electronic device ED shown in FIG. 1, the conductive elements (including the first conductive element CE1 and the second conductive element CE2) in the electronic device ED1 of the present embodiment may not fully fill the via VH in the substrate CB. Specifically, as shown in FIG. 4, when the first conductive element CE1 is disposed in the first sub via SV1, the first conductive element CE1 may not fully fill the first sub via SV1 and surround a sub via SV3. The sidewall of the sub via SV3 may be the side surface of the first conductive element CE1. In such condition, in the top view of the electronic device ED1, the first conductive element CE1 may have a ring structure and surround the sub via SV3. Similarly, when the second conductive element CE2 is disposed in the second sub via SV2, the second conductive element CE2 may not fully fill the second sub via SV2 and surround a sub via SV4. In the top view of the electronic device ED1, the second conductive element CE2 may have a ring structure and surround the sub via SV4. After the first base layer BS1 is bonded to the second base layer BS2, the sub via SV3 and the sub via SV4 may overlap each other to form a via VH′, wherein the via VH′ may penetrate the first conductive element CE1 and the second conductive element CE2. In addition, the via VH′ may further penetrate the conductive layer MA in the first redistribution layer RL1 and the conductive layer MB in the second redistribution layer RL2, but not limited thereto. It should be noted that in the present embodiment, the electronic device ED1 may include or not include the first buffer layer BF1 and/or the second buffer layer BF2, it is not limited in the present embodiment.

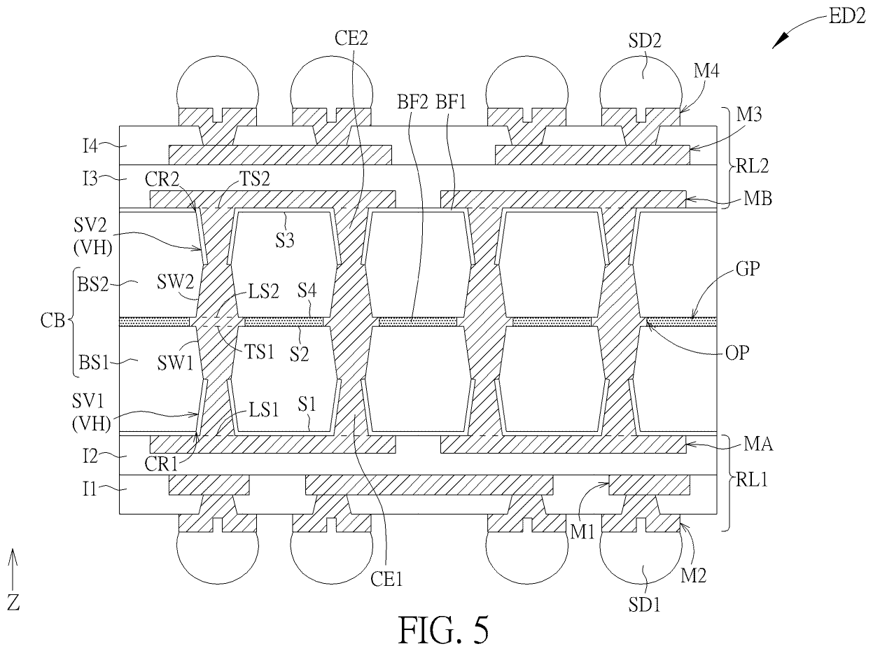

Referring to FIG. 5, FIG. 5 schematically illustrates a cross-sectional view of an electronic device according to a third embodiment of the present disclosure. Compared with the electronic device ED shown in FIG. 1, the first buffer layer BF1 in the electronic device ED2 of the present embodiment may not cover at least a portion of the side surface of the first base layer BS1 (or the sidewall SW1 of the first sub via SV1) and at least a portion of the side surface of the second base layer BS2 (or the sidewall SW2 of the second sub via SV2). Specifically, as shown in FIG. 5, the first buffer layer BF1 may be disposed on the surface S1 and a portion of the side surface of the first base layer BS1 and cover the corner CR1, but not disposed on a portion of the side surface of the first base layer BS1 adjacent to the second base layer BS2. Similarly, the first buffer layer BF1 may be disposed on the surface S3 and a portion of the side surface of the second base layer BS2 and cover the corner CR2, but not disposed on a portion of the side surface of the second base layer BS2 adjacent to the first base layer BS1. In such condition, the first conductive element CE1 may contact the side surface of the first base layer BS1, and the second conductive element CE2 may contact the side surface of the second base layer BS2.

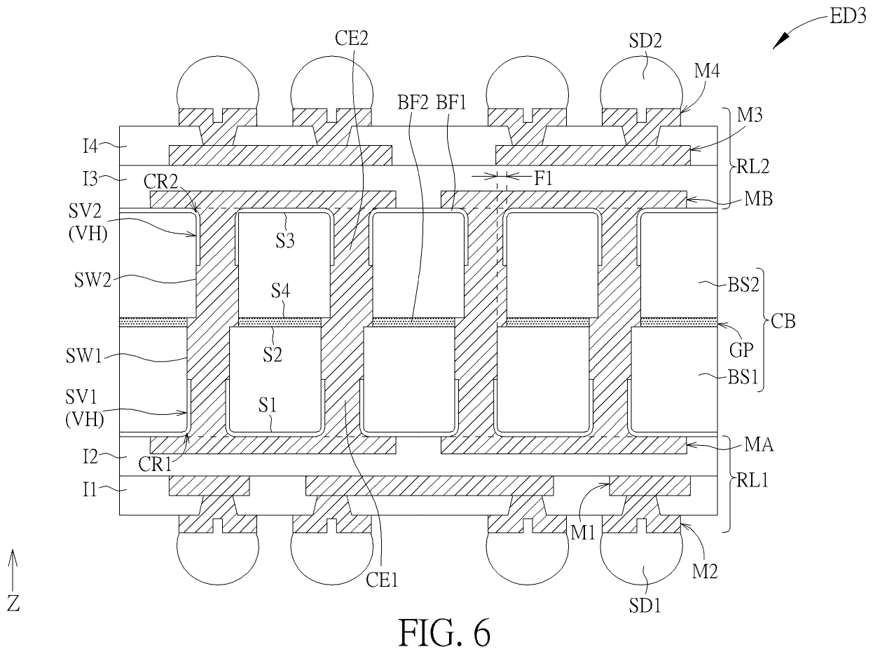

Referring to FIG. 6, FIG. 6 schematically illustrates a cross-sectional view of an electronic device according to a fourth embodiment of the present disclosure. Compared with the electronic device ED shown in FIG. 1, the sub via (including the first sub via SV1 and the second sub via SV2) in the electronic device ED3 of the present embodiment may substantially have the same width at different positions. Specifically, as shown in FIG. 6, in the cross-sectional view of the electronic device ED3, the cross-sectional shape of the first sub via SV1 (or the second sub via SV2) may substantially be rectangular, such that the widths of the first sub via SV1 (or the second sub via SV2) at different depths may substantially be the same. In such condition, the sidewall SW1 of the first sub via SV1 and the sidewall SW2 of the second sub via SV2 may substantially be parallel to the normal direction of the electronic device ED3. In the present embodiment, the corner CR1 and the corner CR2 may be arc-shaped, but not limited thereto. In addition, FIG. 6 shows a structure in which the first sub via SV1 is offset from the second sub via SV2, wherein the definition and range of the offset distance F1 between the first sub via SV1 and the second sub via SV2 may refer to the contents mentioned above, and will not be redundantly described. In some embodiments, the first sub via SV1 may not be offset from the second via SV2. It should be noted that although the first buffer layer BF1 does not cover a portion of the side surface of the first base layer BS1 and a portion of the side surface of the second base layer BS2 in FIG. 6, it is not limited in the present embodiment. In some embodiments, the first buffer layer BF1 may completely cover the side surface of the first base layer BS1 and the side surface of the second base layer BS2. In some embodiments, the electronic device ED3 may not include the first buffer layer BF1.

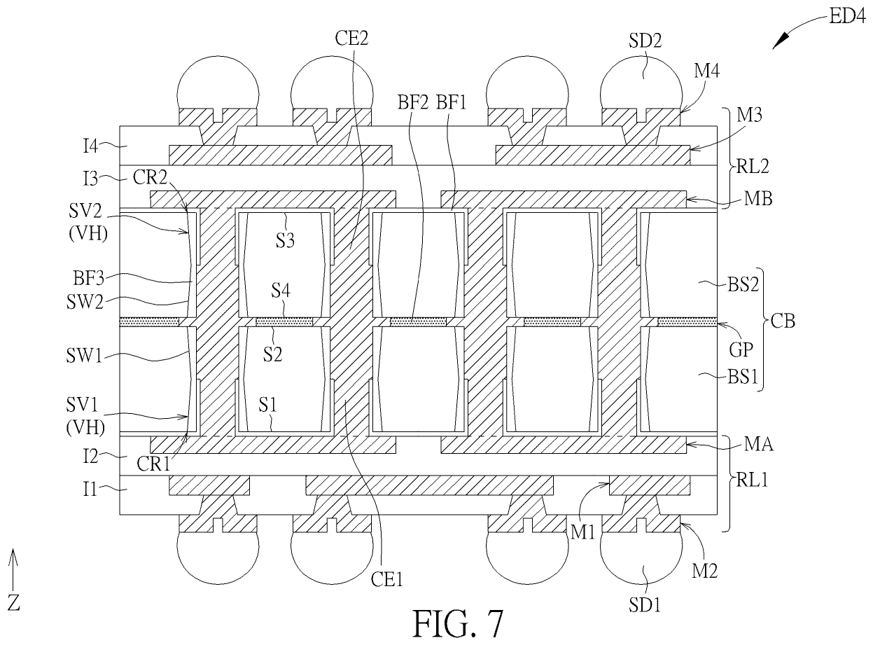

Referring to FIG. 7, FIG. 7 schematically illustrates a cross-sectional view of an electronic device according to a fifth embodiment of the present disclosure. Compared with the electronic device ED shown in FIG. 1, the electronic device ED4 of the present embodiment may further include a third buffer layer BF3. Specifically, as shown in FIG. 7, along a direction perpendicular to the normal direction (the direction Z) of the electronic device ED4, the electronic device ED4 may further include a third buffer layer BF3 disposed on the side surface of the first base layer BS1 (or the sidewall SW1 of the first sub via SV1) and the side surface of the second base layer BS2 (or the sidewall SW2 of the second sub via SV2), wherein the third buffer layer BF3 is disposed between the first base layer BS1 and the first buffer layer BF1 and disposed between the second base layer BS2 and the first buffer layer BF1. In detail, after the first sub via SV1 and the second sub via SV2 are formed, the third buffer layer BF3 may be disposed on the sidewall SW1 of the first sub via SV1 and the sidewall SW2 of the second sub via SV2 at first, and then the first buffer layer BF1, the first conductive element CE1 and the second conductive element CE2 are disposed. In such condition, the first buffer layer BF1 may be disposed on the side surface of the third buffer layer BF3. The third buffer layer BF3 may completely cover the sidewall SW1 and the sidewall SW2, but not limited thereto. In some embodiments, the first buffer layer BF1 may partially cover the side surface of the third buffer layer BF3, as shown in FIG. 7. In some embodiments, the first buffer layer BF1 may completely cover the side surface of the third buffer layer BF3. In some embodiments, the electronic device ED4 may not include the first buffer layer BF1. In such condition, the third buffer layer BF3 may be disposed between the first base layer BS1 and the first conductive element CE1 and disposed between the second base layer BS2 and the second conductive element CE2. In some embodiments, according to the demands of design of the electronic device ED4, the third buffer layer BF3 may be disposed to modify the shapes (such as the cross-sectional shapes) of the first sub via SV1 and the second sub via SV2. In some embodiments, the aspect ratios of the first sub via SV1 and the second sub via SV2 may be increased by disposing the third buffer layer BF3. The material of the third buffer layer BF3 may refer to the material of the first buffer layer BF1 mentioned above, and will not be redundantly described.

It should be noted that the manufacturing method M100 of the electronic device ED may be applied to the electronic devices shown in FIG. 4 to FIG. 7.

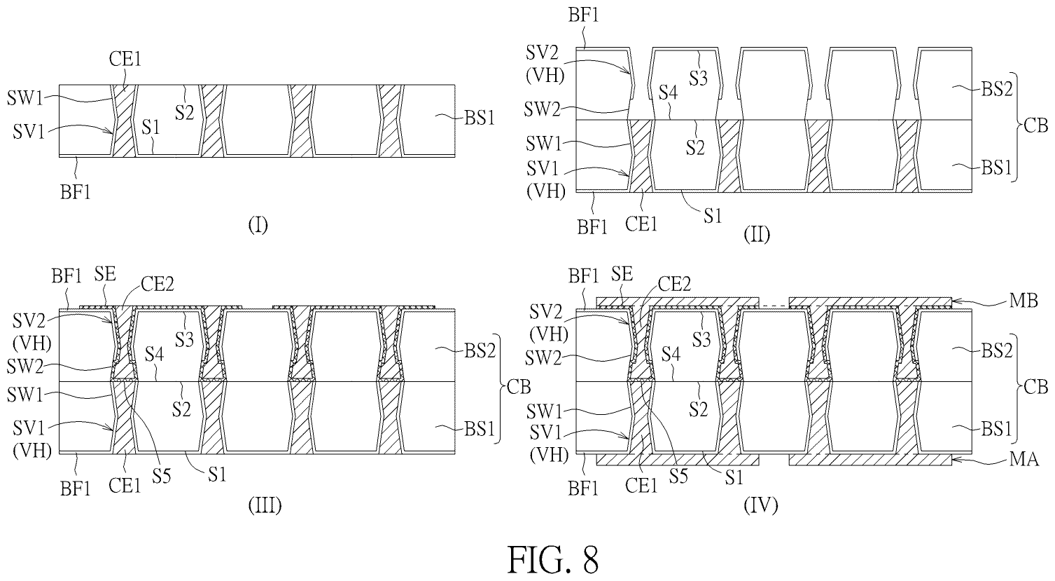

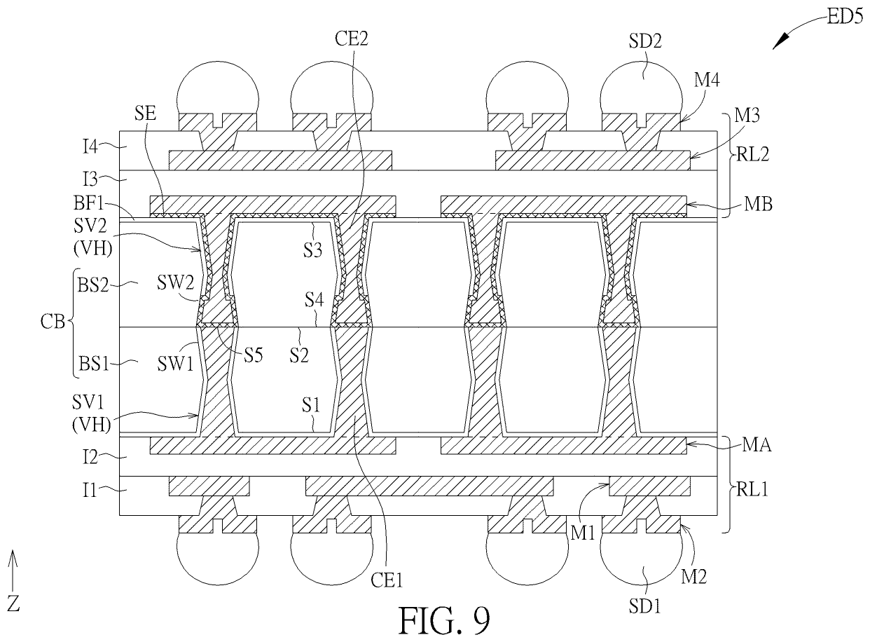

Referring to FIG. 8 to FIG. 9, FIG. 8 schematically illustrates a manufacturing process of an electronic device according to a sixth embodiment of the present disclosure, and FIG. 9 schematically illustrates a cross-sectional view of the electronic device according to the sixth embodiment of the present disclosure. According to the present embodiment, the manufacturing method M200 of the electronic device ED5 may include following steps:
S200: providing a first base layer, and forming a first sub via in the first base layer;
S202: disposing a first buffer layer in at least a portion of the first sub via;
S204: disposing a first conductive element in the first sub via;
S206: providing a second base layer, and forming a second sub via in the second base layer;
S208: bonding the first base layer and the second base layer to form a substrate;
S210: disposing a first buffer layer in at least a portion of the second sub via;
S212: disposing a seed layer in the second sub via;
S214: disposing a second conductive element in the second sub via;
S216: disposing a first redistribution layer at a side of the first base layer opposite to the second base layer; and
S218: disposing a second redistribution layer at a side of the second base layer opposite to the first base layer.

The detail of the steps of the manufacturing method M200 of the electronic device ED5 will be detailed in the following.

As shown in the structure (I) of FIG. 8, the manufacturing method M200 of the electronic device ED5 may include the step S200: providing a first base layer BS1, and forming a first sub via SV1 in the first base layer BS1, the step S202: disposing a first buffer layer BF1 in at least a portion of the first sub via SV1, and the step S204: disposing a first conductive element CE1 in the first sub via SV1, wherein the detail of these steps may refer to the contents of the step S100 to the step S104 mentioned above, and will not be redundantly described. In addition, the manufacturing method M200 of the electronic device ED5 may further include the step S206: providing a second base layer BS2, and forming a second sub via SV2 in the second base layer BS2, wherein the detail thereof may refer to the content of the step S106 mentioned above, and will not be redundantly described.

The manufacturing method M200 of the electronic device ED5 may further include the step S208: bonding the first base layer BS1 and the second base layer BS2 to form a substrate CB. Specifically, as shown in the structure (II) of FIG. 8, after the second sub via SV2 is formed, the second base layer BS1 and the first base layer BS1 may be bonded at first, wherein the second sub via SV2 corresponds to the first sub via SV1 or the first conductive element CE1. In other words, in the present embodiment, the second base layer BS2 may be bonded to the first base layer BS1 at first, and then the second conductive element CE2 is disposed in the second sub via SV2. In the present embodiment, the first base layer BS1 may be directly bonded to the second base layer BS2, that is, the first base layer BS1 directly contacts the second base layer BS2, but not limited thereto. In some embodiments, the second buffer layer BF2 may be included between the first base layer BS1 and the second base layer BS2.

After the first base layer BS1 and the second base layer BS2 are bonded, the manufacturing method M200 of the electronic device ED5 may further include the step S210: disposing a first buffer layer BF1 in at least a portion of the second sub via SV2. Specifically, the first buffer layer BF1 may be disposed on the surface S3 and side surface (or the sidewall SW2 of the second sub via SV2) of the second base layer BS2. In the present embodiment, the first buffer layer BF1 may expose a portion of the side surface of the second base layer BS2 adjacent to the first base layer BS1, but not limited thereto. In such condition, the first buffer layer BF1 disposed in the second sub via SV2 may not contact the first buffer layer BF1 disposed in the first sub via SV1. In some embodiments, the first buffer layer BF1 may completely cover the side surface of the second base layer BS2. In such condition, the first buffer layer BF1 disposed in the second sub via SV2 may contact the first buffer layer BF1 disposed in the first sub via SV1.

According to the present embodiment, the manufacturing method M200 of the electronic device ED5 may further include the step S212: disposing a seed layer SE in the second sub via SV2. Specifically, the seed layer SE may be disposed corresponding to the predetermined disposition position of the second conductive element CE2, which may facilitate the disposition of the second conductive element CE2 in subsequent process. For example, as shown in the structure (III) of FIG. 8, after the first buffer layer BF1 is disposed on the second base layer BS2, the seed layer SE may be disposed on the surface S3 and the side surface of the second base layer BS2 and the surface S5 of the first conductive element CE1 adjacent to the second base layer BS2. In such condition, the first buffer layer BF1 in the second sub via SV2 may be located between the seed layer SE and the second base layer BS2. In some embodiments, when the first buffer layer BF1 does not completely cover the side surface of the second base layer BS2, the seed layer SE may contact the portion of the side surface of the second base layer BS2 not covered by the first buffer layer BF1. In some embodiments, when the first buffer layer BF1 completely cover the side surface of the second base layer BS2, the seed layer SE may not contact the second base layer BS2. The seed layer SE may for example include copper, titanium or alloys thereof, but not limited thereto.

The manufacturing method M200 of the electronic device ED5 may further include the step S214: disposing a second conductive element CE2 in the second sub via SV2. Specifically, after the seed layer SE is disposed, the second conductive element CE2 may be disposed on the portion of the seed layer SE located in the second sub via SV2. In such condition, at least a portion of the seed layer SE (that is, the portion located on the surface S5 of the first conductive element CE1) may be disposed between the first conductive element CE1 and the second conductive element CE2. Therefore, in the present embodiment, the first conductive element CE1, the second conductive element CE2 and the seed layer SE may serve as the conductive element in the via VH of the substrate CB. As shown in the structure (IV) of FIG. 8, the manufacturing method M200 of the electronic device ED5 may further include disposing the conductive layer MA on the surface S1 of the first base layer BS1 and disposing the conductive layer MB on the surface S3 of the second base layer BS2. It should be noted that the conductive layer MB disposed on the surface S3 of the second base layer BS2 may be disposed on the seed layer SE, but not limited thereto. It should be noted that although it is not shown in FIG. 8, a seed layer may be disposed before the first conductive element CE1 of the electronic device ED5 is disposed, and the first conductive element CE1 may be disposed on the seed layer. In addition, although it is not shown in the figure, before the disposition of the conductive elements (including the first conductive element CE1 and the second conductive element CE2) of the electronic devices in the embodiments above, the step of disposing a seed layer may be performed at first.

After the second conductive element CE2 is disposed, the manufacturing method M200 of the electronic device ED5 may further include the step S216: disposing a first redistribution layer RL1 at a side of the first base layer BS1 opposite to the second base layer BS2, and the step S218: disposing a second redistribution layer RL2 at a side of the second base layer BS2 opposite to the first base layer BS1, wherein the detail thereof may refer to the contents above, and will not be redundantly described. After the first redistribution layer RL1 and the second redistribution layer RL2 are disposed, the electronic device ED5 may be formed, as shown in FIG. 9. It should be noted that the electronic device ED5 may further include other suitable elements or layers, which is not limited to the structure shown in FIG. 9.

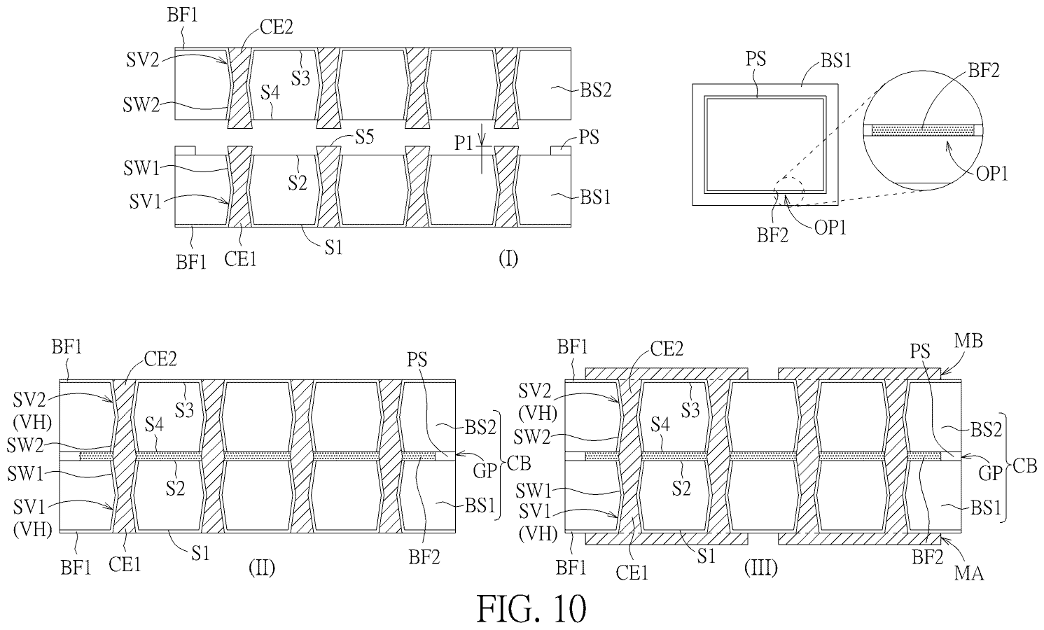

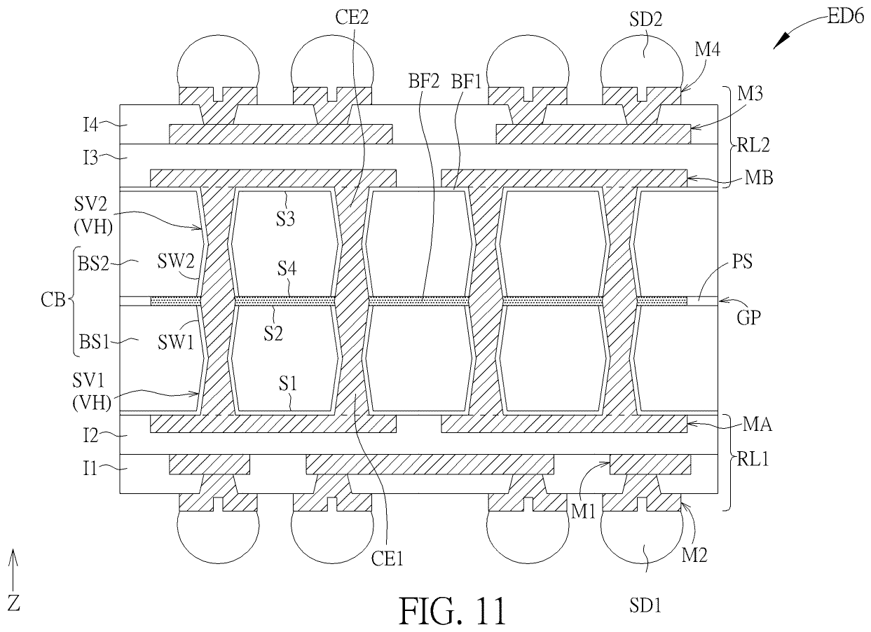

Referring to FIG. 10 to FIG. 11, FIG. 10 schematically illustrates a manufacturing process of an electronic device according to a seventh embodiment of the present disclosure, and FIG. 11 schematically illustrates a cross-sectional view of the electronic device according to the seventh embodiment of the present disclosure. According to the present embodiment, the manufacturing method M300 of the electronic device ED6 may include following steps:
S300: providing a first base layer, and forming a first sub via in the first base layer;
S302: disposing a first buffer layer in at least a portion of the first sub via;
S304: disposing a first conductive element in the first sub via;
S306: providing a second base layer, and forming a second sub via in the second base layer;
S308: disposing a first buffer layer in at least a portion of the second sub via;
S310: disposing a second conductive element in the second sub via;
S312: disposing a spacer on a surface of the first base layer;
S314: bonding the first base layer and the second base layer to form a substrate;
S316: disposing a second buffer layer between the first base layer and the second base layer through an opening of the spacer;
S318: disposing a first redistribution layer at a side of the first base layer opposite to the second base layer; and
S320: disposing a second redistribution layer at a side of the second base layer opposite to the first base layer.

The detail of the steps of the manufacturing method M300 of the electronic device ED6 will be detailed in the following.

The manufacturing method M300 of the electronic device ED6 may include the step S300 to the step S310: disposing the first buffer layer BF1 and the first conductive element CE1 in the first sub via SV1 of the first base layer BS1 and disposing the first buffer layer BF1 and the second conductive element CE2 in the second sub via SV2 of the second base layer BS2, wherein the detail thereof may refer to the contents above, and will not be redundantly described. It should be noted that in the present embodiment, when the first conductive element CE1 is disposed in the first sub via SV1, the first conductive element CE1 may protrude from the surface (that is, the surface S2) of the first base layer BS1 used for bonding with the second base layer BS2. As shown in the structure (I) of FIG. 10, the first conductive element CE1 may protrude from the surface S2 of the first base layer BS1, and a distance P1 may be included between the surface S5 of the first conductive element CE1 and the surface S2 of the first base layer BS1. The distance P1 may for example be defined as the distance between the highest point of the surface S5 and the highest point of the surface S2, but not limited thereto. In the present embodiment, the distance P1 may range from 50 nm to 2 μm (that is, 50 nm≤P1≤2 μm), but not limited thereto. Similarly, the second conductive element CE2 may protrude from the surface S4 of the second base layer BS2 used for bonding with the first base layer BS1, and the definition and range of the distance at which the second conductive element CE2 protrudes from the surface S4 may refer to the description of the above-mentioned distance P1, and will not be redundantly described. By making the first conductive element CE1 and the second conductive element CE2 protrude from the surface S2 of the first base layer BS1 and the surface S4 of the second base layer BS2 respectively, the situation that the first conductive element CE1 and the second conductive element CE2 are not easily in contact (or electrically connected) due to excessively great roughness of the surface S2 and the surface S4 may be reduced.

According to the present embodiment, the manufacturing method M300 of the electronic device ED6 may further include the step S312: disposing a spacer PS on a surface of the first base layer BS1. Specifically, as shown in the structure (I) of FIG. 10, before bonding the first base layer BS1 and the second base layer BS2, the spacer PS may be disposed on the surface S2 of the first base layer BS1 used for bonding with the second base layer BS2. The spacer PS may have at least one opening OP1. Specifically, observing the electronic device ED6 from a top view, the spacer PS disposed on the first base layer BS1 may substantially have a ring structure and include at least one gap, and the gap is the opening OP1 of the spacer PS. The spacer PS may include a plurality of openings OP1, which is not limited to the structure (I) of FIG. 10. It should be noted that in some embodiments, the spacer PS may be optionally disposed on the surface S4 of the second base layer BS2 used for bonding with the first base layer BS1.

The manufacturing method M300 of the electronic device ED6 may further include the step S314: bonding the first base layer BS1 and the second base layer BS2 to form a substrate CB. Specifically, as shown in the structure (II) of FIG. 10, after the spacer PS is disposed, the first base layer BS1 and the second base layer BS2 may be bonded, such that the first conductive element CE1 may contact the second conductive element CE2 (for example, through heating, but not limited thereto). After the substrate CB is formed, the spacer PS may be disposed between the first base layer BS1 and the second base layer BS2.

The manufacturing method M300 of the electronic device ED6 may further include the step S316: disposing a second buffer layer BF2 between the first base layer BS1 and the second base layer BS2 through an opening OP1 of the spacer PS. Specifically, as shown in the structure (II) of FIG. 10, after bonding the first base layer BS1 and the second base layer BS2, the second buffer layer BF2 may be filled into the gap GP between the first base layer BS1 and the second base layer BS2 through the opening OP1 of the spacer PS. That is, the second buffer layer BF2 is disposed between the first base layer BS1 and the second base layer BS2 after bonding the first base layer BS1 and the second base layer BS2. In such condition, the spacer PS may surround the second buffer layer BF2, or the spacer PS may be used to define the disposition range of the second buffer layer BF2. “The spacer PS surrounds the second buffer layer BF2” described herein may represent that in the cross-sectional view of the electronic device ED6, the spacer PS contacts at least a portion of the side surface of the second buffer layer BF2. After that, through heating, pressurizing, leveling, curing, combinations thereof or other suitable processes, a portion of the second buffer layer BF2 may fill the opening OP1, but not limited thereto. That is, in the top view of the electronic device ED6 (as shown in the structure (I) of FIG. 10), a portion of the second buffer layer BF2 may be disposed in the opening OP1. It should be noted that the structure (I) of FIG. 10 only shows the portion of the second buffer layer BF2 in the opening OP1, but not show the portion of the second buffer layer BF2 surrounded by the spacer PS.

After the second buffer layer BF2 is disposed, the manufacturing method M300 of the electronic device ED6 may further include the step S318: disposing a first redistribution layer RL1 at a side of the first base layer BS1 opposite to the second base layer BS2, and the step S320: disposing a second redistribution layer RL2 at a side of the second base layer BS2 opposite to the first base layer BS1, wherein the detail thereof may refer to the contents above, and will not be redundantly described. After the first redistribution layer RL1 and the second redistribution layer RL2 are disposed, the electronic device ED6 may be formed, as shown in FIG. 11. It should be noted that the electronic device ED6 may further include other suitable elements or layers, which is not limited to the structure shown in FIG. 11.

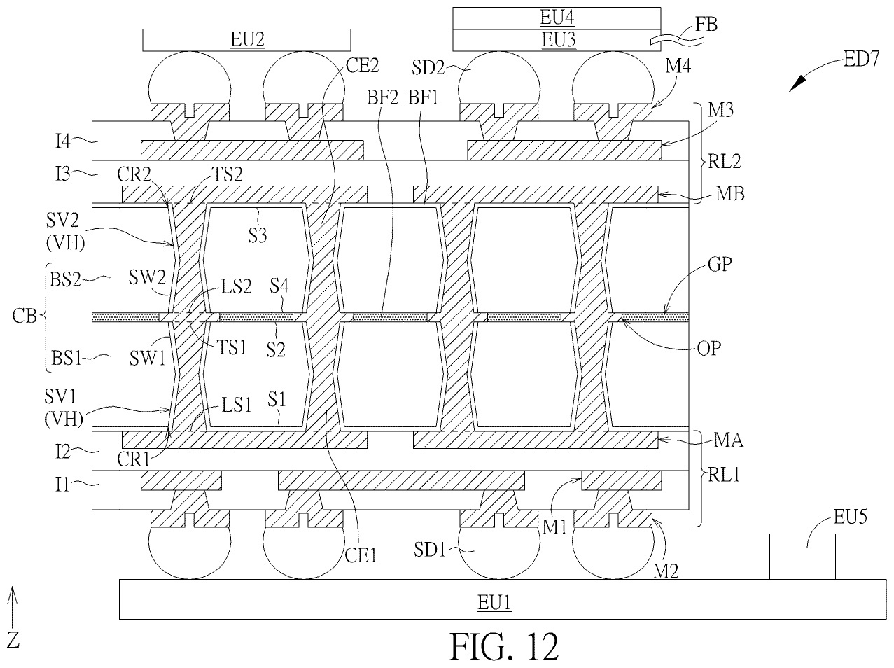

Referring to FIG. 12, FIG. 12 schematically illustrates a cross-sectional view of an electronic device according to an eighth embodiment of the present disclosure. It should be noted that the substrate CB of the electronic device ED7 of the present embodiment may be the substrate in any one of the embodiments of the present disclosure, which is not limited to what is shown in FIG. 12. According to the present embodiment, the electronic device ED7 may further include electronic units electrically connected to the first redistribution layer RL1 and the second redistribution layer RL2 respectively. For example, as shown in FIG. 12, the electronic device ED7 may include an electronic unit EU1 electrically connected to the first redistribution layer RLI and an electronic unit EU2 and an electronic unit EU3 electrically connected to the second redistribution layer RL2. Specifically, the first redistribution layer RL1 may be bonded to the electronic unit EU1 through the solder ball SD1, and the second redistribution layer RL2 may be bonded to the electronic unit EU2 and the electronic unit EU3 through the solder ball SD2. Therefore, the electronic unit EU2 and the electronic unit EU3 may be electrically connected to the electronic unit EU1 through the second redistribution layer RL2, the substrate CB (or the conductive element in the via VH of the substrate CB) and the first redistribution layer RL1. For example, the electronic unit EU2 may include an application specific integrated circuit (ASIC) chip or any suitable chip. The electronic unit EU3 may be electrically connected to an electronic unit EU4. For example, the electronic unit EU3 may include a photonic integrated circuit (PIC) and may be connected to an optical fiber FB, and the electronic unit EU4 may include an electrical integrated circuit (EIC) to convert a light signal into an electrical signal. The electronic unit EU1 may include a circuit board, wherein the chip and the photonic integrated circuit may be electrically connected to the circuit board through the second redistribution layer RL2, the substrate CB and the first redistribution layer RL1. In such condition, the electronic device ED7 may further include an electronic unit EU5 bonded on the circuit board (the electronic unit EU1), and the electronic unit EU2 and the electronic unit EU3 may be electrically connected to the electronic unit EU5, but not limited thereto. The electronic unit EU5 may for example be bonded on the electronic unit EU1 through surface mount technology (SMT), but not limited thereto. It should be noted that the electronic units mentioned above may include any suitable element according to the demands of the design of the electronic device ED7, which is not limited to the contents mentioned above.

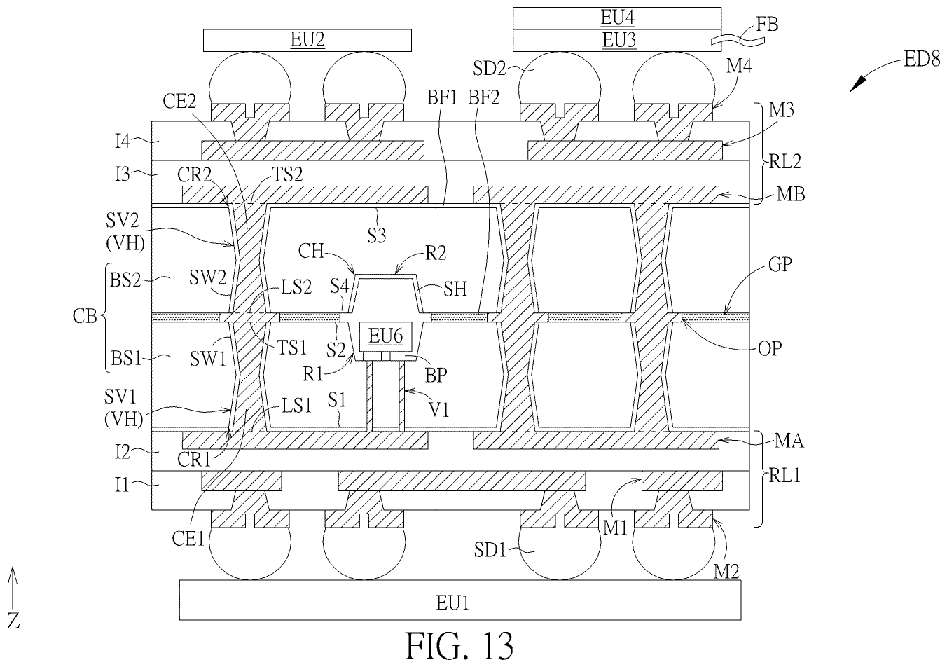

Referring to FIG. 13, FIG. 13 schematically illustrates a cross-sectional view of an electronic device according to a ninth embodiment of the present disclosure. It should be noted that the substrate CB of the electronic device ED8 of the present embodiment may be the substrate in any one of the embodiments of the present disclosure, which is not limited to what is shown in FIG. 13. According to the present embodiment, the electronic device ED8 may further include a cavity structure CH located in the substrate CB. The cavity structure CH may be formed of a first recess R1 and a second recess R2. Specifically, the surface S2 of the first base layer BS1 adjacent to the second base layer BS2 may include the first recess R1, and the surface S4 of the second base layer BS2 adjacent to the first base layer BS1 may include the second recess R2, wherein when the first base layer BS1 and the second base layer BS2 are bonded, the first recess R1 may overlap the second recess R2 to define the cavity structure CH located in the substrate CB. The first recess R1 may be formed by removing a portion of the first base layer BS1, and the second recess R2 may be formed by removing a portion of the second base layer BS2. In the present embodiment, the cavity structure CH may be used to accommodate electronic units, but not limited thereto. For example, the electronic device ED8 may further include an electronic unit EU6, wherein the electronic unit EU6 is disposed in the cavity structure CH. The electronic unit EU6 may be electrically connected to the first conductive element CE1, thereby being electrically connected to other electronic units through the first conductive element CE1. Specifically, the electronic device ED8 may further include a bonding pad BP disposed in the cavity structure CH, wherein the electronic unit EU6 may be bonded on the bonding pad BP. In addition, the first base layer BS1 may include the via V1, wherein the via V1 may be connected between the bonding pad BP and the first conductive element CE1. Therefore, the bonding pad BP may be electrically connected to the first conductive element CE1 through the via V1, thereby electrically connecting the electronic unit EU6 to the first conductive element CE1. In the present embodiment, the electronic device ED8 may further include a shielding layer SH, wherein the shielding layer SH may be located between the electronic unit EU6 and other electronic units. For example, as shown in FIG. 13, the shielding layer SH may be disposed in the second recess R2, thereby being located between the electronic unit EU6 and the electronic unit EU2. Therefore, the signal interference between the electronic unit EU6 and other electronic units may be reduced. It should be noted that the substrate CB may include multiple cavity structures CH, or multiple electronic units may be disposed in a cavity structure CH, which is not limited to what is shown in FIG. 13.

In such condition, the manufacturing method of the electronic device ED8 of the present embodiment may further include following steps before bonding the first base layer BS1 and the second base layer BS2:
S400: forming a first recess in the first base layer;
S402: disposing an electronic unit in the first recess; and
S404: forming a second recess in the second base layer.

The manufacturing method of the electronic device ED8 may further include the step S400: forming a first recess R1 in the first base layer BS1. Specifically, the first recess R1 may be disposed on the surface S2 of the first base layer BS1 used for bonding with the second base layer BS2. In some embodiments, the first recess R1 and the first sub via SV1 may be formed at the same time, or the first recess R1 and the first sub via SV1 may be formed in the same process. In some embodiments, the first recess R1 and the first sub via SV1 may be formed in any suitable order.

After the first recess R1 is formed, the step S402: disposing an electronic unit EU6 in the first recess R1 may be performed. Specifically, the bonding pad BP may be disposed in the first recess R1 at first, and then the electronic unit EU6 is disposed on the bonding pad BP. In such condition, the manufacturing method of the electronic device ED8 may further include forming the via V1 in the first base layer BS1. The disposition position of the via V1 may correspond to the disposition position of the bonding pad BP. The via V1 and the first recess R1 and/or the first sub via SV1 may be formed at the same time or formed through any suitable order, it is not limited in the present embodiment.

The manufacturing method of the electronic device ED8 may further include the step S404: forming a second recess R2 in the second base layer BS2. Specifically, the second recess R2 may be disposed on the surface S4 of the second base layer BS2 used for bonding with the first base layer BS1. The second recess R2 and the second sub via SV2 may be formed at the same time or formed in any suitable order. In the present embodiment, the manufacturing method of the electronic device ED8 may further include disposing the shielding layer SH in the second recess R2, such that the shielding layer SH may be located between the electronic unit EU6 and other electronic units after the first base layer BS1 and the second base layer BS2 are bonded. It should be noted that in some embodiments, the electronic unit ED6 may be disposed in the second recess R2, and the shielding layer SH may be disposed in the first recess R1. The forming methods of other elements and layers of the electronic device ED8 may refer to the manufacturing method of the electronic device of any one of the embodiments of the present disclosure.

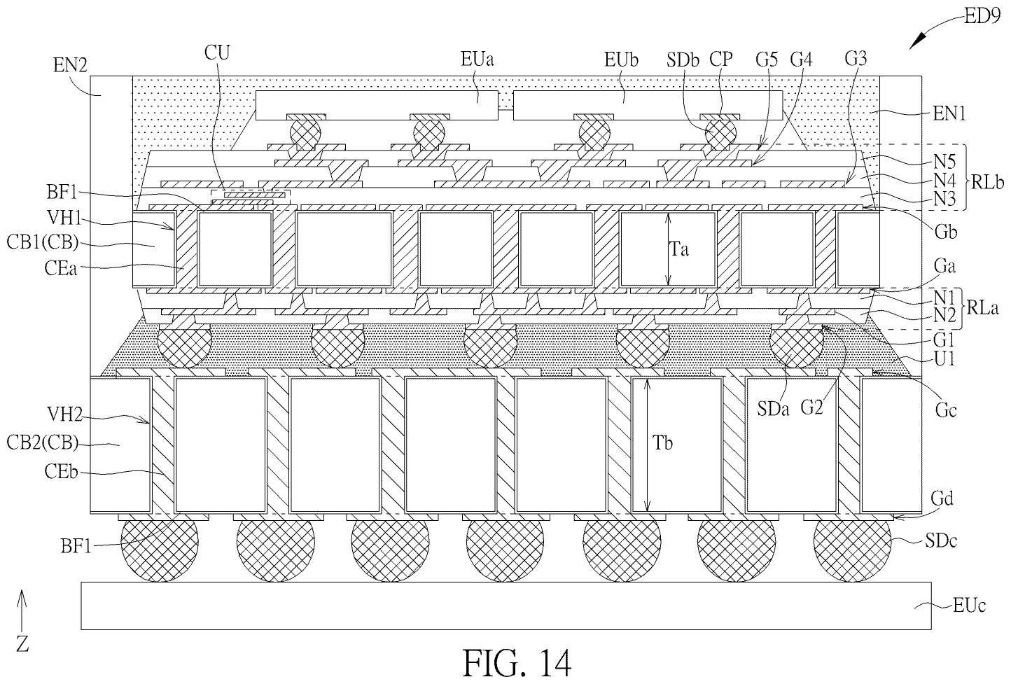

Referring to FIG. 14, FIG. 14 schematically illustrates a cross-sectional view of an electronic device according to a tenth embodiment of the present disclosure. According to the present embodiment, the electronic device ED9 may include two substrates CB, that is, the first substrate CB1 and the second substrate CB2. It should be noted that in order to simplify the figure, FIG. 14 does not show the detail of the structures of the first substrate CB1 and the second substrate CB2. The structures of the first substrate CB1 and the second substrate CB2 may refer to the structure of the substrate CB in any one of the embodiments mentioned above. In detail, the first substrate CB1 may include a via VH1, and a conductive element CEa is disposed in the via VH1, wherein the first substrate CB1 may be formed of the first base layer BS1 and the second base layer BS2 mentioned above, the via VH1 may be formed of the first sub via SV1 and the second sub via SV2 mentioned above, and the conductive element CEa may be formed of the first conductive element CE1 and the second conductive element CE2 mentioned above. Similarly, the second substrate CB2 may include a via VH2, and a conductive element CEb is disposed in the via VH2, wherein the second substrate CB2 may be formed of the first base layer BS1 and the second base layer BS2 mentioned above, the via VH2 may be formed of the first sub via SV1 and the second sub via SV2 mentioned above, and the conductive element CEb may be formed of the first conductive element CE1 and the second conductive element CE2 mentioned above. The electronic device ED9 may further include the first buffer layer BF1 disposed in the via VH1 and the via VH2, and the detail thereof may refer to the contents above, which is not limited to what is shown in FIG. 14.

According to the present embodiment, the first substrate CB1 may be disposed on the second substrate CB2, and the conductive element CEa in the first substrate CB1 may be electrically connected to the conductive element CEb in the second substrate CB2. Specifically, the electronic device ED9 may include a redistribution layer RLa disposed at a side of the first substrate CB1 adjacent to the second substrate CB2. That is, the redistribution layer RLa may be disposed between the first substrate CB1 and the second substrate CB2. As shown in FIG. 14, the redistribution layer RLa may include an insulating layer N1, an insulating layer N2, a conductive layer G1, a conductive layer G2 and a conductive layer Ga, wherein the conductive layer Ga is located between the conductive element CEa and the insulating layer N1, the conductive layer G1 is located between the insulating layer N1 and the insulating layer N2, and the conductive layer G2 is located at a side of the insulating layer N2 opposite to the insulating layer N1. The conductive layer Ga may contact the conductive element CEa to be electrically connected to the conductive element CEa. The conductive layer G1 may be electrically connected to the conductive layer Ga (for example, through the via in the insulating layer N1), and the conductive layer G2 may be electrically connected to the conductive layer G1 (for example, through the via in the insulating layer N2). It should be noted that the structure of the redistribution layer RLa is exemplary, it is not limited in the present embodiment. The electronic device ED9 may further include a solder ball SDa located below the conductive layer G2 and be electrically connected to the conductive layer G2, wherein the solder ball SDa may be used for bonding the first substrate CB1 and the redistribution layer RLa to the second substrate CB2. In such condition, the conductive element CEa in the first substrate CB1 may be electrically connected to the conductive element CEb in the second substrate CB2 through the redistribution layer RLa and the solder ball SDa. Specifically, the electronic device ED9 may further include a conductive layer Gc located between the solder ball SDa and the conductive element CEb, wherein the conductive layer Gc contacts the conductive element CEb and be electrically connected to the conductive element CEb, and the solder ball SDa may be electrically connected to the conductive layer Gc, thereby being electrically connected to the conductive element CEb. The electronic device ED9 may further include an underfill layer U1, wherein the underfill layer U1 may be disposed between the first substrate CB1 and the second substrate CB2 and surround the solder ball SDa. In some embodiments, the underfill layer U1 may further surround the redistribution layer RLa. Specifically, in the cross-sectional view of the electronic device ED9, the underfill layer U1 may contact at least a portion of the side surface of the redistribution layer RLa. The underfill layer U1 may include any suitable insulating material, such as epoxy resin or acrylic resin, but not limited thereto.

According to the present embodiment, the first substrate CB1 may have a thickness Ta, and the second substrate CB2 may have a thickness Tb, wherein the thickness Ta may be less than the thickness Tb. In other words, in the electronic device ED9, the thickness of the substrate CB in the lower side may be greater than the thickness of the substrate CB in the upper side. The thickness Ta may be defined as the maximum thickness of the first substrate CB1, wherein the thickness Ta may be the sum of the thickness of the first base layer BS1, the thickness of the second base layer BS2 and/or the thickness of the gap between the first base layer BS1 and the second base layer BS2 in the first substrate CB1, but not limited thereto. The definition of the thickness Tb may be the same as the definition of the thickness Ta, and will not be redundantly described. Through the design of the thicknesses mentioned above. the supporting effect of the substrate CB in the lower side (that is, the second substrate CB2) may be improved, thereby improving the reliability of the electronic device ED9.

As shown in FIG. 14, the electronic device ED9 may further include a redistribution layer RLb disposed at a side of the first substrate CB1 away from the second substrate CB2. The redistribution layer RLb may include an insulating layer N3, an insulating layer N4, an insulating layer N5, a conductive layer G3, a conductive layer G4, a conductive layer G5 and a conductive layer Gb, wherein the conductive layer Gb contacts the conductive element CEa, the insulating layer N3 is located on the first substrate CB1 and covers the conductive layer Gb, the conductive layer G3 is located on the insulating layer N3, the insulating layer N4 is located on the insulating layer N3 covers the conductive layer G3, the conductive layer G4 is located on the insulating layer N4, the insulating layer N5 is located on the insulating layer N4 and covers the conductive layer G4, and the conductive layer G5 is located on the insulating layer N5, but not limited thereto. The conductive layer G5 may be electrically connected to the conductive layer G4 through the via in the insulating layer N5, and the conductive layer G4 may be electrically connected to the conductive layer G3 through the via in the insulating layer N4. The electronic device ED9 may further include a conductive element CU located on the first substrate CB1, wherein the conductive element CU may be used for electrically connecting the conductive layer Gb and the conductive layer G3. The conductive element CU may for example include a capacitor, an inductor, other suitable passive elements or combinations of the above-mentioned elements. The conductive layer Gb may be electrically connected to the conductive element CEa. Therefore, the conductive element CEa in the first substrate CB1 may be electrically connected to other electronic units through the redistribution layer RLb. For example, the electronic device ED9 may include a solder ball SDb, an electronic unit EUa and an electronic unit EUb, wherein the solder ball SDb may be electrically connected between the conductive layer G5 and the electronic unit EUa (and/or the electronic unit EUb). Specifically, the solder ball SDb may be disposed on the conductive layer G5 and be bonded to the conductive pad CP of the electronic unit EUa and/or the electronic unit EUb, but not limited thereto. The electronic device ED9 may further include an underfill layer U2, wherein the underfill layer U2 may be disposed on the redistribution layer RLb and surround the solder ball SDb. In some embodiments, the underfill layer U2 may further surround the electronic unit EUa and the electronic unit EUb, that is, the underfill layer U2 may contact at least a portion of the side surface of the electronic unit EUa and at least a portion of the side surface of the electronic unit EUb in the cross-sectional view of the electronic device ED9. The material of the underfill layer U2 may refer to the material of the underfill layer U1 mentioned above.

In the present embodiment, the electronic device ED9 may further include encapsulation layer EN1, wherein the encapsulation layer EN1 may be located on the first substrate CB1 and surround the redistribution layer RLb, the electronic unit EUa and the electronic unit EUb. That is, the encapsulation layer EN1 may be used to encapsulate the elements or layers on the first substrate CB1. The encapsulation layer EN1 may include any suitable encapsulating material, such as epoxy molding compound (EMC), but not limited thereto. In addition, the electronic device ED9 may further include an encapsulation layer EN2 located on the second substrate CB2, wherein the encapsulation layer EN2 may be used to encapsulate the elements or layers on the second substrate CB2. In other words, in the present embodiment, an encapsulating process may be performed on the elements or layers on the first substrate CB1 through the encapsulation layer EN1 at first, and then another encapsulating process may be performed on the elements or layers on the second substrate CB2 through the encapsulation layer EN2. The material of the encapsulation layer EN2 may refer to the material of the encapsulation layer EN1.

In the present embodiment, the electronic device ED9 may further include a solder ball SDc, wherein the solder ball SDc is located below the conductive element CEb and may be electrically connected to the conductive element CEb. Specifically, the electronic device ED9 may further include a conductive layer Gd located between the conductive element CEb and the solder ball SDc, wherein the conductive layer Gd contacts the conductive element CEb and be electrically connected to the conductive element CEb, and the solder ball SDc may be electrically connected to the conductive element CEb through the conductive layer Gd. Therefore, the conductive element CEb may be electrically connected to other electronic units through the solder ball SDc. For example, the electronic device ED9 may further include an electronic unit EUc, and the conductive element CEb may be electrically connected to the electronic unit EUc through the solder ball SDc. The electronic unit EUc may for example include a circuit board, but not limited thereto. In such condition, the electronic unit EUa and the electronic unit EUb may be electrically connected to the electronic unit EUc through the first substrate CB1 (or the conductive element CEa in the first substrate CB1) and the second substrate CB2 (or the conductive element CEb in the second substrate CB2). It should be noted that the electronic device ED9 may further include other suitable elements or layers, which is not limited to the structure shown in FIG. 14.

In summary, an electronic device and a manufacturing method thereof are provided by the present disclosure, wherein the substrate of the electronic device is formed by bonding the first base layer and the second base layer, such that the via in the substrate may be formed of the first sub via in the first base layer and the second sub via in the second base layer. In such condition, the substrate having the via with high aspect ratio may be formed while reducing the difficulty of forming the conductive element in the via.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate having a via, wherein the substrate comprises:
a first base layer including a first sub via, wherein the first sub via penetrates the first base layer; and
a second base layer bonded to the first base layer, wherein the second base layer includes a second sub via, the second sub via penetrates the second base layer, and the first sub via and the second sub via overlap each other to define the via; and
a first buffer layer disposed in at least a portion of the via, wherein the first sub via has a pore size, the first sub via and the second sub via have an overlapping region, the overlapping region has an overlapping width, and a difference between the pore size and the overlapping width ranges from 0.01 micrometers to 5 micrometers.

2. The electronic device of claim 1, further comprising a first conductive element and a second conductive element, wherein the first conductive element is disposed in the first sub via, and the second conductive element is disposed in the second sub via.

3. The electronic device of claim 2, further comprising a seed layer, wherein at least a portion of the seed layer is disposed between the first conductive element and the second conductive element.

4. The electronic device of claim 1, further comprising a second buffer layer disposed between the first base layer and the second base layer, wherein the second buffer layer includes an opening, and the opening exposes the first sub via and the second sub via.

5. The electronic device of claim 4, further comprising a spacer disposed between the first base layer and the second base layer, wherein the spacer surrounds the second buffer layer.

6. The electronic device of claim 5, wherein in a top view of the electronic device, the spacer has at least one opening, and a portion of the second buffer layer is disposed in the at least one opening.

7. The electronic device of claim 4, wherein the opening of the second buffer layer has a width, and the width is greater than or equal to the pore size of the first sub via.

8. The electronic device of claim 1, wherein a gap is included between the first base layer and the second base layer, and a thickness of the gap is less than or equal to 3 micrometers.

9. The electronic device of claim 1, further comprising a third buffer layer disposed between the first base layer and the first buffer layer and disposed between the second base layer and the first buffer layer.

10. The electronic device of claim 1, further comprising a first redistribution layer and a second redistribution layer, wherein the first redistribution layer is disposed at a side of the first base layer opposite to the second base layer, and the second redistribution layer is disposed at a side of the second base layer opposite to the first base layer.

11. The electronic device of claim 1, further comprising:
a cavity structure located in the substrate; and
an electronic unit disposed in the cavity structure.

12. The electronic device of claim 1, wherein the first base layer and the second base layer include glass.

13. A manufacturing method of an electronic device, comprising:
providing a first base layer, and forming a first sub via in the first base layer;
providing a second base layer, and forming a second sub via in the second base layer;
disposing a first conductive element in the first sub via;
disposing a second conductive element in the second sub via; and
bonding the first base layer and the second base layer to form a substrate, wherein the first sub via overlaps the second sub via to define a via,
wherein the first sub via has a pore size, the first sub via and the second sub via have an overlapping region, the overlapping region has an overlapping width, and a difference between the pore size and the overlapping width ranges from 0.01 micrometers to 5 micrometers.

14. The manufacturing method of claim 13, wherein the manufacturing method further comprises disposing a first buffer layer in at least a portion of the first sub via and at least a portion of the second sub via before disposing the first conductive element in the first sub via and disposing the second conductive element in the second sub via.

15. The manufacturing method of claim 13, wherein the manufacturing method further comprises disposing a second buffer layer on a surface of the first base layer before bonding the first base layer and the second base layer, wherein the first base layer is bonded to the second base layer through the second buffer layer.

16. The manufacturing method of claim 15, further comprising forming an opening in the second buffer layer, wherein the opening overlaps the first sub via.

17. The manufacturing method of claim 13, wherein the manufacturing method further comprises disposing a spacer on a surface of the first base layer before bonding the first base layer and the second base layer, wherein the spacer includes at least one opening, and the spacer is disposed between the first base layer and the second base layer after bonding the first base layer and the second base layer to form the substrate.

18. The manufacturing method of claim 17, further comprising disposing a second buffer layer between the first base layer and the second base layer through the at least one opening of the spacer.

19. The manufacturing method of claim 13, wherein before bonding the first base layer and the second base layer, the manufacturing method further comprises:
forming a first recess in the first base layer;
disposing an electronic unit in the first recess; and
forming a second recess in the second base layer,
wherein the first recess overlaps the second recess to form a cavity structure after bonding the first base layer and the second base layer, and the electronic unit is located in the cavity structure.

20. The manufacturing method of claim 13, further comprising:
disposing a first redistribution layer at a side of the first base layer opposite to the second base layer; and
disposing a second redistribution layer at a side of the second base layer opposite to the first base layer.
